(19) United States
(12) Patent Application Publication
(10) Pub. No.: US 2026/0114149 A1
(43) Pub. Date: Apr. 23, 2026

(54) TOUCH DISPLAY DEVICE

(71) Applicant: LG Display Co., Ltd., Seoul (KR)

(72) Inventors: Junggi Kim, Paju-si (KR); SeongYong Uhm, Paju-si (KR); Dohyung Kim, Paju-si (KR); Jinsuk Lee, Paju-si (KR); Jihyeop Kim, Paju-si (KR); Kyunghee Kim, Paju-si (KR); HyunSik Kim, Paju-si (KR)

(73) Assignee: LG Display Co., Ltd., Seoul (KR)

(21) Appl. No.: 19/093,769

(22) Filed: Mar. 28, 2025

(30) Foreign Application Priority Data
Oct. 17, 2024 (KR) 10-2024-0141878

(51) Int. Cl. H10K 59/40; G06F 3/041; H10K 59/80

(52) U.S. Cl. CPC H10K 59/40; G06F 3/04164; H10K 59/873

(57) ABSTRACT

A touch display device including a display area and a non-display area, a pixel electrode disposed on the substrate, a common electrode disposed on the pixel electrode, a first encapsulation layer disposed on the common electrode, a second encapsulation layer disposed on the first encapsulation layer, a third encapsulation layer disposed on the second encapsulation layer, and a plurality of touch metals disposed on the third encapsulation layer. The second encapsulation layer includes a first organic layer having a first permittivity, and a second organic layer having a second permittivity different from the first permittivity and disposed outside than the first organic layer such that parasitic capacitances are within a predefined range.

### CROSS-REFERENCE TO RELATED APPLICATION

This application claims priority to Korean Patent Application No. 10-2024-0141878, filed in the Republic of Korea on Oct. 17, 2024, the entire contents of which are hereby incorporated by reference into the present application.

### BACKGROUND

### Field

Embodiments of the disclosure relate to a touch display device.

### Description of Related Art

Touch display devices provide an input scheme that allows users easier and more intuitive and convenient entry of information or commands without the need for buttons, a keyboard, a mouse, or other typical input means. In more detail, the touch display device includes touch electrodes for touch sensing, and touch routing lines for connecting the touch electrodes to pad portions. Also, touch metals for forming the touch electrodes and the touch routing lines are disposed on an encapsulation layer for protecting an organic-based light emitting element in the display panel from physical impact, oxygen, and/or moisture.

Recently, developments are being made to enable mass production or large-scale panel manufacturing of display panels for touch display devices, shorten panel manufacturing times, and enable eco-friendly panel manufacturing.

### SUMMARY

Accordingly, an object of the present disclosure is to address the above-noted and other problems.

Another object of the present disclosure is to provide a touch display device having an encapsulation structure that enables a shortened panel manufacturing time, eco-friendly panel manufacturing, mass production, or large-scale panel manufacturing.

Still another object of the present disclosure is to provide a touch display device having a touch sensor structure that enables shortened panel manufacturing time, eco-friendly panel manufacturing, mass production, or large-scale panel manufacturing.

Yet another object of the present disclosure is to provide a touch display device capable of enhancing touch sensitivity.

Another object of the present disclosure is to provide a touch display device having an encapsulation structure capable of enhancing touch uniformity.

To achieve these and other advantages and in accordance with the purpose of the present disclosure, as embodied and broadly described herein, the present disclosure provides in one aspect a touch display device having a substrate including a display area displaying an image and a non-display area outside the display area, a pixel electrode disposed on the substrate, a common electrode disposed on the pixel electrode, a first encapsulation layer disposed on the common electrode, a second encapsulation layer disposed on the first encapsulation layer, a third encapsulation layer disposed on the second encapsulation layer, and a plurality of touch metals disposed on the third encapsulation layer.

In addition, the second encapsulation layer can include two or more organic layers in a horizontal direction. For example, the second encapsulation layer can include a first organic layer having a first permittivity, and a second organic layer having a second permittivity different from the first permittivity and disposed further outside than the first organic layer.

Further, a touch display device according to embodiments of the disclosure can include a substrate including a display area displaying an image and a non-display area outside the display area, a pixel electrode disposed on the substrate, a common electrode disposed on the pixel electrode, an organic layer disposed on the common electrode, and a plurality of touch metals disposed on the organic layer. Further, the organic layer can include two or more different organic materials in a horizontal direction from the display area to the non-display area.

According to embodiments of the disclosure, it is possible to shorten the panel manufacturing time and enable eco-friendly panel manufacturing, mass production, or large-scale panel manufacturing by forming an encapsulation structure through an inkjet printing process. Further, it is possible to shorten the panel manufacturing time and enable eco-friendly panel manufacturing, mass production, or large-scale panel manufacturing by forming a touch sensor structure on an encapsulation structure formed through an inkjet printing process. It is also possible to enhance touch sensitivity by increasing the uniformity of touch sensitivity by forming an encapsulation layer with two or more different organic materials in a horizontal direction.

Further scope of applicability of the present invention will become apparent from the detailed description given hereinafter. However, the detailed description and specific examples, while indicating preferred embodiments of the invention, are given by illustration only, since various changes and modifications within the spirit and scope of the invention will become apparent to those skilled in the art from this detailed description.

### BRIEF DESCRIPTION OF THE DRAWINGS

The above and other objects, features, and advantages of the disclosure will be more clearly understood from the following detailed description, taken in conjunction with the accompanying drawings, in which:

FIG. 1 is a view illustrating a configuration of a touch display device according to embodiments of the disclosure;

FIG. 2 illustrates a touch display device according to embodiments of the disclosure;

FIG. 3 is a cross-sectional view illustrating a display panel according to embodiments of the disclosure;

FIG. 4 is a plan view illustrating a display panel according to embodiments of the disclosure;

FIGS. 5 and 6 are views illustrating a touch sensor structure of a touch display device according to embodiments of the disclosure;

FIG. 7 illustrates a second encapsulation layer formed through a deposition process in a display panel of a touch display device according to embodiments of the disclosure;

FIG. 8 illustrates a second encapsulation layer formed through an inkjet printing process in a display panel of a touch display device according to embodiments of the disclosure;

FIGS. 9 and 10 are graphs illustrating changes in the position of a second encapsulation layer formed through an inkjet printing process in a display panel of a touch display device according to embodiments of the disclosure;

FIG. 11 illustrates parasitic capacitors formed in touch metals disposed on a display panel according to embodiments of the disclosure;

FIGS. 12 and 13 illustrate a second encapsulation layer having a touch uniformity enhancing structure in a touch display device and a display panel including the second encapsulation layer according to an embodiment of the disclosure;

FIGS. 14 and 15 illustrate a second encapsulation layer having a touch uniformity enhancing structure in a touch display device and a display panel including the second encapsulation layer according to an embodiment of the disclosure; and

FIGS. 16 and 17 illustrate a second encapsulation layer having a touch uniformity enhancing structure in a touch display device and a display panel including the second encapsulation layer according to an embodiment of the disclosure.

### DETAILED DESCRIPTION OF THE EMBODIMENTS

Hereinafter, embodiments of the disclosure are described in detail with reference to the accompanying drawings. In assigning reference numerals to components of each drawing, the same components can be assigned the same numerals even when they are shown on different drawings. As used herein, when a component “includes,” “has,” or “is composed of” another component, the component can add other components unless the component “only” includes, has, or is composed of” the other component. As used herein, the singular forms “a”, “an” and “the” are intended to include the plural forms as well, unless the context clearly indicates otherwise.

Such denotations as “first,” “second,” “A,” “B,” “(a),” and “(b),” can be used in describing the components of the disclosure. These denotations are provided merely to distinguish a component from another, and the essence, order, or number of the components are not limited by the denotations.

In describing the positional relationship between components, when two or more components are described as “connected”, “coupled” or “linked”, the two or more components can be directly “connected”, “coupled” or “linked””, or another component can intervene. Here, the other component can be included in one or more of the two or more components that are “connected”, “coupled” or “linked” to each other. When such terms as, e.g., “after”, “next to”, “after”, and “before”, are used to describe the temporal flow relationship related to components, operation methods, and fabricating methods, it can include a non-continuous relationship unless the term “immediately” or “directly” is used.

When a component is designated with a value or its corresponding information (e.g., level), the value or the corresponding information can be interpreted as including a tolerance that can arise due to various factors (e.g., process factors, internal or external impacts, or noise).

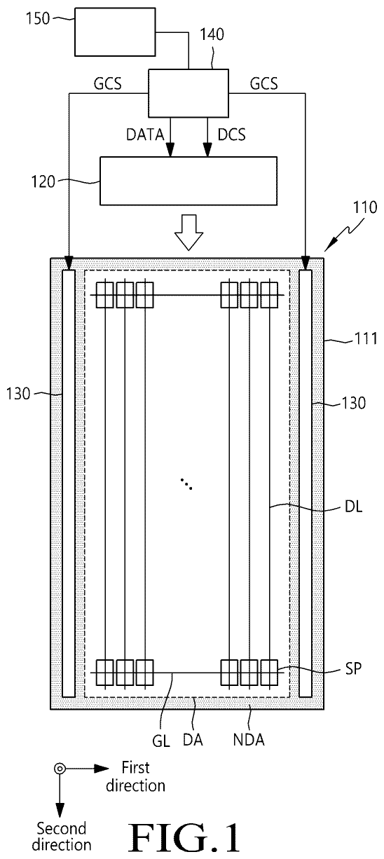

Hereinafter, various embodiments of the disclosure are described in detail with reference to the accompanying drawings. FIG. 1 is a view illustrating a configuration of a touch display device 100 according to embodiments of the disclosure.

Referring to FIG. 1, a transparent touch display device 100 according to embodiments of the disclosure includes a display panel 110 and display driving circuits, as components for displaying images. The display driving circuit drives the display panel 110 and includes a data driving circuit 120, a gate driving circuit 130, and a controller 140, but embodiments of the disclosure are not limited thereto.

As shown, the display panel 110 includes a substrate 111 and a plurality of subpixels SP disposed on the substrate 111. Further, the substrate 111 includes a display area DA and a non-display area NDA. In particular, the display area DA is an area where images can be displayed, and can also be referred to as an active area. As shown, a plurality of subpixels SP for image display are disposed in the display area DA. Further, the non-display area NDA is an area where no image is displayed and is an area outside the display area DA. The non-display area NDA can also be referred to as a bezel (or bezel area) and includes a pad area (also referred to as a pad portion).

For example, the non-display area NDA can include a first non-display area around the display area DA, a second non-display area including a pad area, and a bending area between the first non-display area and the second non-display area. In the pad area, a driving circuit can be connected or bonded (or attached). As the bending area is bent, the bending area and the second non-display area can be disposed behind the first non-display area to be invisible from the front. Further, the first non-display area can have a very small size. Embodiments of the disclosure are not limited thereto.

Also, no or little change can be made to the non-display area NDA shown to the user when the user views the touch display device 100 from the front, but embodiments of the disclosure are not limited thereto.

In addition, the touch display device 100 according to embodiments of the disclosure can be a self-luminous touch display device in which the display panel 110 emits light by itself, but embodiments of the disclosure are not limited thereto. When the touch display device 100 is a self-luminous touch display device, each of the subpixels SP can include a light emitting element.

For example, the touch display device 100 can be an organic light emitting touch display device in which the light emitting element is implemented as an organic light emitting diode (OLED). As another example, the touch display device 100 can be an inorganic light emitting touch display device in which the light emitting element is implemented as an inorganic material-based light emitting diode. As another example, the display device 100 can be a quantum dot touch display device in which the light emitting element is implemented as a quantum dot which is self-luminous semiconductor crystal. As still another example, the touch display device 100 can be a micro LED touch display device or a mini LED touch display device.

The structure of each of the subpixels SP can vary according to the type of the touch display device 100. For example, when the touch display device 100 is a self-luminous touch display device in which the subpixels SP emit light by themselves, each subpixel SP can include a light emitting element that emits light by itself, one or more transistors, and one or more capacitors, but embodiments of the disclosure are not limited thereto.

In addition, various types of signal lines for driving a plurality of subpixels SP can be disposed on the substrate 111 of the display panel 110. For example, various types of signal lines can include data lines DL transferring data signals (also referred to as data voltages or image signals) to subpixels SP and gate lines GL transferring gate signals (also referred to as scan signals) to the subpixels SP.

The data lines DL and the gate lines GL also cross each other. Further, each gate line GL can be disposed to extend in a first direction (e.g., a row direction or column direction), and each data line DL can be disposed to extend in a second direction (e.g., a column direction or row direction) different from the first direction.

According to embodiments of the disclosure, e.g., the first direction can be the row direction, and the second direction can be the column direction. As another example, the first direction can be the column direction, and the second direction can be the row direction. Also, the row direction and the column direction are relative directions. For example, the column direction can be the row direction depending on the viewpoint, and the row direction can be the column direction depending on the viewpoint. For convenience, described below is an example in which each data line DL is disposed in the column direction, and each gate line GL is disposed in the row direction, but embodiments of the disclosure are not limited thereto. In embodiments of the disclosure, the angle between the first direction and the second direction can be 90 degrees or can be an angle different from 90 degrees.

In addition, the data driving circuit 120 is for driving the data lines DL, and outputs data signals to the data lines DL. Also, the data driving circuit 120 can receive digital image data DATA from the controller 140 and can convert the received image data DATA into analog data signals (or also referred to as data voltages) and output the signals to the data lines DL.

For example, the data driving circuit 120 can be connected with the display panel 110 by a tape automated bonding (TAB) method or connected to a bonding pad of the display panel 110 by a chip on glass (COG) or chip on panel (COP) method or can be implemented by a chip on film (COF) method and connected with the display panel 110, but embodiments of the disclosure are not limited thereto.

In addition, the data driving circuit 120 can be connected to one side (e.g., an upper or lower side) of the display panel 110. As another example, depending on the driving scheme or the panel design scheme, data driving circuits 120 can be connected with both sides (e.g., both the upper and lower sides) of the display panel 110, or two or more of the four sides of the display panel 110. The data driving circuit 120 can also be connected outside the display area DA of the display panel 110, but as another example, the data driving circuit 120 can be disposed in the display area DA of the display panel 110.

Further, the gate driving circuit 130 is driving the gate lines GL, and outputs gate signals to the gate lines GL. In particular, the gate driving circuit 130 can receive a first gate voltage corresponding to a turn-on voltage (or also referred to as a turn-on level voltage) and a second gate voltage corresponding to a turn-off voltage (or also referred to as a turn-off level voltage) together with various gate driving control signals GCS, generate gate signals including a section having the first gate voltage and a section having the second gate voltage for a predetermined time (e.g., one frame time), and supply the generated gate signals to the gate lines GL. For example, the turn-on level voltage can be a high level voltage, and the turn-off level voltage can be a low level voltage. As another example, the turn-on level voltage can be a low level voltage, and the turn-off level voltage can be a high level voltage.

In the touch display device 100 according to embodiments of the disclosure, the gate driving circuit 130 can be embedded, in a gate in panel (GIP) type, in the display panel 110, but embodiments of the disclosure are not limited thereto. When the gate driving circuit 130 is of the gate in panel type, the gate driving circuit 130 can be formed on the substrate 111 of the display panel 110 during the manufacturing process of the display panel 110. When the gate driving circuit 130 is of a gate-in-panel type, the gate driving circuit 130 can be referred to as a gate-in-panel circuit (GIPC).

For example, the gate driving circuit 130 can be disposed in the non-active area NDA of the display panel 110. As another example, the gate driving circuit 130 can be disposed in the display area DA of the display panel 110. Also, the gate driving circuit 130 can be disposed in a first partial area in the display area DA (e.g., a left area or a right area in the display area DA). As another example, the gate driving circuit 130 can be disposed in a first partial area in the display area DA (e.g., a left area or right area in the display area DA) and a second partial area (e.g., a right area or left area in the display area DA). As still another example, the gate driving circuit 130 can be disposed over the entire display area DA.

When the gate driving circuit 130 is disposed in the display area DA of the display panel 110, the gate driving circuit 130 can vertically overlap the subpixels SP disposed in the display area DA. For example, the gate driving circuit 130 can vertically overlap the light emitting elements and transistors included in the disposed subpixels SP in the display area DA. In addition, the gate driving circuit 130 can vertically overlap a plurality of light emitting elements and a plurality of transistors included in a plurality of subpixels SP disposed in the display area DA. The gate driving circuit 130 also includes a plurality of transistors. Each transistor included in the gate driving circuit 130 can include an active layer including a first semiconductor material, and each transistor included in the subpixels SP can include an active layer including a second semiconductor material. For example, the first semiconductor material and the second semiconductor material can be substantially identical. As another example, the first semiconductor material and the second semiconductor material can be different from each other. Also, the first semiconductor material can be a silicon-based semiconductor material (e.g., low temperature poly silicon), and the second semiconductor material can be an oxide semiconductor material. In addition, the active layer can be, but is not limited to, a semiconductor layer.

Further, the controller 140 is a device for controlling the data driving circuit 120 and the gate driving circuit 130 and can control driving timings for the data lines DL and driving timings for the gate lines GL. In more detail, the controller 140 can supply a data driving control signal DCS to the data driving circuit 120 to control the data driving circuit 120 and can supply a gate driving control signal GCS to the gate driving circuit 130 to control the gate driving circuit 130.

In addition, the controller 140 can receive input image data from the host system 150 and supply image data DATA to the data driving circuit 120 based on the input image data. The controller 140 can be implemented as a separate component from the data driving circuit 120, or the controller 140 and the data driving circuit 120 can be integrated into an integrated circuit (IC).

Further, the controller 140 can be a timing controller used in display technology, a control device that can perform other control functions as well as the functions of the timing controller, or a control device other than the timing controller, or can be a circuit in the control device. The controller 140 can be implemented as various circuits or electronic components, such as an integrated circuit (IC), a field programmable gate array (FPGA), an application specific integrated circuit (ASIC), or a processor, but is not limited thereto.

In addition, the controller 140 can be mounted on a printed circuit board or a flexible printed circuit and can be electrically connected with the data driving circuit 120 and the gate driving circuit 130 through the printed circuit board or the flexible printed circuit. The controller 140 can also transmit/receive signals to/from the data driving circuit 120 according to one or more predetermined interfaces. In particular, the interface can include, e.g., a low voltage differential signaling (LVDS) interface, an embedded clock point-point interface (EPI), and a serial peripheral interface (SPI), but embodiments of the disclosure are not limited thereto.

Further, the touch display device 100 according to embodiments of the disclosure can provide not only an image display function, but also a touch sensing function of detecting whether a touch is made by a touch object, such as a finger or a pen, or detecting the position of a touch. The touch display device 100 can be a mobile terminal, such as a smart phone or a tablet, or a monitor or television (TV) in various sizes but, without limited thereto, can be a display in various types and various sizes capable of displaying information or images.

In addition, the touch display device 100 according to embodiments of the disclosure can further include an electronic device such as a camera (image sensor), a detection sensor, or the like. For example, the detection sensor can be a sensor that detects an object or a human body by receiving light such as infrared rays, ultrasonic waves, or ultraviolet rays, but embodiments of the disclosure are not limited thereto.

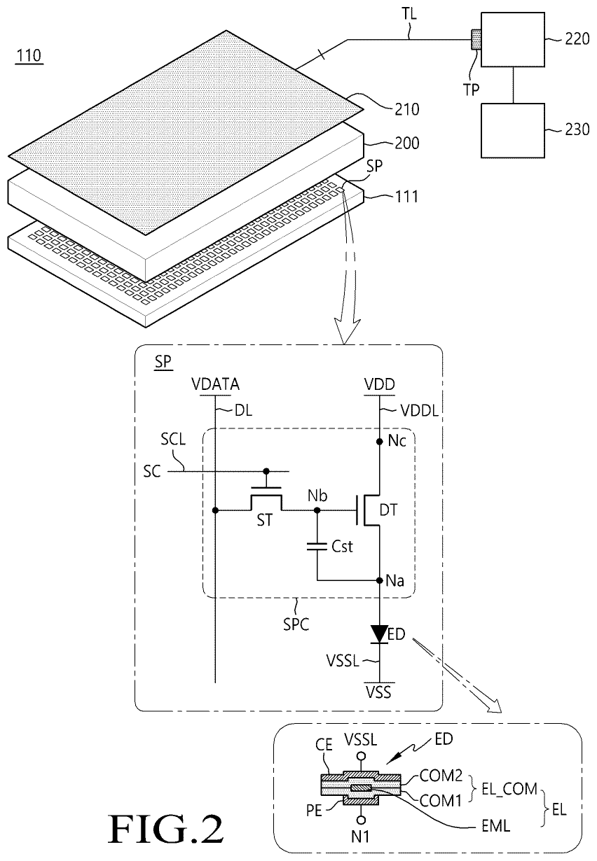

Next, FIG. 2 illustrates a touch display device 100 according to embodiments of the disclosure. Referring to FIG. 2, the display panel 110 includes a substrate 111 having subpixels SP and an encapsulation layer 200 on the substrate 111. The encapsulation layer 200 can also be referred to as an encapsulation substrate or an encapsulation unit.

Referring to FIG. 2, when the touch display device 100 is a self-luminous touch display device, each subpixel SP disposed on the substrate 111 can include a light emitting element ED and a subpixel circuit SPC for driving the light emitting element ED. As shown in FIG. 2, the subpixel circuit SPC includes a plurality of transistors and at least one capacitor for driving the light emitting element ED, but embodiments of the disclosure are not limited thereto. In the disclosure, the subpixel circuit SPC drives the light emitting element ED by supplying a driving current to the light emitting element ED at a predetermined timing. The light emitting element ED can thus be driven by a driving current to emit light.

In addition, the transistors include a driving transistor DT for driving the light emitting element ED and a scan transistor ST that is turned on or off according to the scan signal SC. In particular, the driving transistor DT supplies a driving current to the light emitting element ED, and the scan transistor ST controls the electrical state of a corresponding node in the subpixel circuit SPC or the state or operation of the driving transistor DT. The capacitor can include a storage capacitor Cst for maintaining a constant voltage during a frame.

To drive the subpixel SP, a data signal VDATA as an image signal and a scan signal SC which is a type of gate signal can be applied to the subpixel SP. Further, for driving the subpixel SP, a common driving signal including the driving voltage VDD and the base voltage VSS can be applied to the subpixel SP. Further, as shown, the light emitting element ED includes a pixel electrode PE, an intermediate layer EL, and a common electrode CE, and the intermediate layer EL is disposed between the pixel electrode PE and the common electrode CE.

For example, the pixel electrode PE can be disposed in each subpixel SP, and the common electrode CE can be commonly disposed in all the subpixels SP. Also, the pixel electrode PE can be an anode, and the common electrode CE can be a cathode. As another example, the pixel electrode PE can be a cathode, and the common electrode CE can be an anode. For convenience, the pixel electrode PE is described as an anode, and the common electrode CE is described as a cathode.

When the light emitting element ED is an organic light emitting element, the intermediate layer EL can include a light emitting layer EML, a first common intermediate layer COM1 between the pixel electrode PE and the light emitting layer EML, and a second common intermediate layer COM2 between the light emitting layer EML and the common electrode CE. The first common intermediate layer COM1 and the second common intermediate layer COM2 can be collectively referred to as a common intermediate layer EL_COM.

In addition, the light emitting layer EML can be disposed for each subpixel SP or can be disposed commonly over a plurality of subpixels SP. The common intermediate layer EL_COM can also be commonly disposed across the subpixels SP, but embodiments of the disclosure are not limited thereto. In other words, the light emitting layer EML can be disposed for each emission area or disposed commonly across a plurality of emission areas.

The common intermediate layer EL_COM can be commonly disposed across a plurality of emission areas and non-emission areas, but embodiments of the disclosure are not limited thereto. For example, the first common intermediate layer COM1 can include a hole injection layer HIL, an electron blocking layer EBL, and a hole transport layer HTL, but embodiments of the disclosure are not limited thereto. The second common intermediate layer COM2 can include an electron transport layer ETL, a hole blocking layer HBL, and an electron injection layer EIL, but embodiments of the disclosure are not limited thereto.

Further, the hole injection layer HIL can inject holes from the pixel electrode PE to the hole transport layer HTL, and the hole transport layer HTL can transport holes to the light emitting layer EML. Also, the electron injection layer EIL can inject electrons from the common electrode CE to the electron transport layer ETL, and the electron transport layer ETL can transport electrons to the light emitting layer EML.

For example, the common electrode CE can be electrically connected to the base voltage line VSSL. Also, the base voltage VSS, which is one type of the common voltage, can be applied to the common electrode CE through the base voltage line VSSL. The pixel electrode PE can be electrically connected directly or indirectly (through another transistor) to the first node Na of the driving transistor DT of each subpixel SP. In the disclosure, “base voltage VSS” can also be referred to as a first common voltage, a low-potential power voltage, or a low-potential voltage, and “base voltage line VSSL” can also be referred to as a first common voltage line, a low-potential power voltage line, or a low-potential voltage line.

Each light emitting element ED can include portions where the pixel electrode PE, the light emitting layer EML in the intermediate layer LE, and the common electrode CE overlap. A predetermined light emitting area can be formed by each light emitting element ED. For example, the light emitting area of each light emitting element ED can include an overlapping area of the pixel electrode PE, the light emitting layer EML in the intermediate layer EL, and the common electrode CE.

Also, the light emitting element ED can be an organic light emitting diode (OLED), an inorganic light emitting diode (LED), a quantum dot light emitting element, a micro LED, or a mini LED, but embodiments of the disclosure are not limited thereto. For example, when the light emitting element ED is an organic light emitting diode (OLED), the intermediate layer EL of the light emitting element ED can include an intermediate layer EL including an organic material.

In addition, the driving transistor DT is for supplying a driving current to the light emitting element ED, and can be connected between a driving voltage line VDDL and the light emitting element ED. As shown in FIG. 2, the driving transistor DT can include a first node Na, a second node Nb, and a third node Nc. In particular, the first node Na is electrically connected to the light emitting element ED, the second node Nb receives a data signal VDATA, and the third node Nc receives a driving voltage VDD, which is another type of common voltage, from the driving voltage line VDDL. The driving transistor DT is thus connected to the first node Na and the third node Nc. In the disclosure, “driving voltage VDD” can also be referred to as a second common voltage, a high-potential power voltage, or a high-potential voltage, and “driving voltage line VDDL” can also be referred to as a second common voltage line, a low-potential power voltage line, or a low-potential voltage line.

In the driving transistor DT, the second node Nb can be a gate node, the first node Na can be a source node or a drain node, and the third node Nc can be a drain node or a source node. Hereinafter, for convenience, the second node Nb is described as a gate node, the first node Na is described as a source node, and the third node Nc is described as a drain node, but embodiments of the disclosure are not limited thereto.

In addition, the scan transistor ST included in the subpixel circuit SPC illustrated in FIG. 2 can be a switching transistor for transferring the data signal VDATA, which is an image signal, to the second node Nb, which is the gate node of the driving transistor DT. The scan transistor ST can be turned on and off by the scan signal SC, which is a type of gate signal applied through the scan line SCL, which is a type of the gate line GL, to control electrical connection between the second node Nb of the driving transistor DT and the data line DL. The drain electrode or the source electrode of the scan transistor ST can be electrically connected to the data line DL, the source electrode or the drain electrode of the scan transistor ST can be electrically connected to the second node Nb of the driving transistor DT, and the gate electrode of the scan transistor ST can be electrically connected to the scan line SCL.

Further, the storage capacitor Cst can be electrically connected between the first node Na and second node Nb of the driving transistor DT. As shown, the storage capacitor Cst can include at least one capacitor electrode electrically connected to the first node Na of the driving transistor DT or corresponding to the first node Na of the driving transistor DT, and at least one capacitor electrode electrically connected to the second node Nb of the driving transistor DT or corresponding to the second node Nb of the driving transistor DT.

In addition, the capacitor Cst can be an external capacitor intentionally designed to be outside the driving transistor DT, but not a parasite capacitor (e.g., Cgs or Cgd) which is an internal capacitor that can be present between the first node Na and the second node Nb of the driving transistor DT, but embodiments of the disclosure are not limited thereto. Each of the driving transistor DT and the scan transistor ST can be an n-type transistor or a p-type transistor, but embodiments of the disclosure are not limited thereto. For example, one of the driving transistor DT and the scan transistor ST can be either an n-type transistor or a p-type transistor.

In addition, the display panel 110 can have a top emission structure or a bottom emission structure. When the display panel 110 has a top emission structure, at least a portion of the subpixel circuit SPC can overlap at least a portion of the light emitting element ED in a vertical direction. Accordingly, the area of the emission area and the aperture ratio can increase. When the display panel 110 has a bottom emission structure, the subpixel circuit SPC may not overlap the light emitting element ED in the vertical direction.

As illustrated in FIG. 2, the subpixel circuit SPC can have a 2T (Transistor)1C (Capacitor) structure including two transistors DT and ST and one capacitor Cst. In some instances, the subpixel circuit SPC can further include one or more transistors or one or more capacitors.

For example, the subpixel circuit SPC can have a 3TIC structure including 3 transistors and 1 capacitor. In another example, the subpixel circuit SPC can have an 8TIC structure including 8 transistors and 1 capacitor. As yet another example, the subpixel circuit SPC can have a 6T2C structure including 6 transistors and 2 capacitors. The subpixel circuit SPC can also have a 7T1C structure including 7 transistors and 1 capacitor. Embodiments of the disclosure are not limited thereto.

Depending on the structure of the subpixel circuit SPC, the type and number of gate lines or the gate signals supplied to the subpixel SP can vary. Further, the type and the number of common driving signals supplied to the subpixel SP can vary depending on the structure of the subpixel circuit SPC.

Because the circuit elements (e.g., the light emitting element ED implemented as an organic light emitting diode (OLED) including an organic material) in each subpixel SP are vulnerable to external moisture or oxygen, the encapsulation layer 200 can be disposed on the display panel 110. In particular, the encapsulation layer 200 prevents external moisture or oxygen from penetrating into circuit elements (e.g., the light emitting element ED). The encapsulation layer 200 can also be configured in various forms so that the light emitting elements ED do not contact moisture or oxygen. For example, the encapsulation layer 200 can be constituted of two or more layers in which organic films and inorganic films are alternately stacked, but embodiments of the disclosure are not limited thereto.

Referring to FIG. 2, the touch display device 100 includes a touch sensor layer 210 in which a touch sensor is formed, and a touch sensing circuit that senses the touch sensor formed in the touch sensor layer 210 to determine the presence of a touch or touch coordinates, to provide a touch sensing function. Here, the touch sensor layer 210 can also be referred to as a touch unit or touch sensing unit.

As shown in FIG. 2, the touch sensing circuit can include a touch driving circuit 220 configured to drive and sense the touch sensor formed in the touch sensor layer 210 to generate and output touch sensing data, and a touch controller 230 configured to determine the presence of a touch or touch coordinates using the touch sensing data provided from the touch driving circuit 220.

The touch sensor layer 210 is a layer in which the touch sensor is formed, and the touch sensor can be composed of a plurality of touch electrodes. In addition the touch sensor layer 210 can be disposed outside the display panel 110 and can be configured as a separate touch panel from the display panel 110. In this instance, the touch panel and the display panel 110 can be separately manufactured or can be combined during an assembly process.

As another example, the touch sensor layer 210 can be embedded in the display panel 110. When the touch sensor layer 210 is included inside the display panel 110, the touch sensor layer 210 can be formed on the substrate 111, together with signal lines and electrodes related to display driving, during the manufacturing process of the display panel 110. For example, the touch sensor layer 210 can be disposed on the encapsulation layer 200. For convenience, the touch sensor layer 210 embedded in the display panel 110 is described below.

When the touch sensor layer 210 is embedded in the display panel 110, the display panel 110 can further include, in addition to the plurality of touch electrodes corresponding to the touch sensors, a plurality of touch pads TP to which the touch driving circuit 220 is electrically connected, and a plurality of touch routing lines TL electrically connecting the plurality of touch electrodes and the plurality of touch pads TP. Here, the touch routing lines TL can also be referred to as touch lines. Further, the touch routing lines TL can correspond to touch channels.

In addition, the touch driving circuit 220 can supply a touch driving signal to at least one of the plurality of touch electrodes and can sense at least one of the plurality of touch electrodes to generate touch sensing data. Further, the touch sensing circuit can perform touch sensing in a self-capacitance sensing scheme or a mutual-capacitance sensing scheme.

When the touch sensing circuit performs touch sensing in the self-capacitance sensing scheme, the touch sensing circuit can perform touch sensing based on a capacitance between each touch electrode and the touch object (e.g., finger or pen). According to the self-capacitance sensing scheme, each touch electrode can serve both as a driving touch electrode and as a sensing touch electrode. Further, the touch driving circuit can drive all or some of the touch electrodes and sense all or some of the touch electrodes.

When the touch sensing circuit performs touch sensing in the mutual-capacitance sensing scheme, the touch sensing circuit can perform touch sensing based on capacitance between two adjacent touch electrodes. According to the mutual-capacitance sensing scheme, the plurality of touch electrodes are divided into driving touch electrodes and sensing touch electrodes. In addition, the touch driving circuit can drive the driving touch electrodes and sense the sensing touch electrodes. Touch routing lines connected to the driving touch electrodes can be referred to as driving touch routing lines, and touch routing lines connected to the sensing touch electrodes can be referred to as sensing touch routing lines.

Further, the touch driving circuit 220 and the touch controller 230 can be implemented as separate devices or as a single device. Also, the touch driving circuit 220 and the data driving circuit 120 can be implemented as separate devices or as a single device.

The touch display device 100 can further include a power supply circuit for supplying various types of power to the display driver integrated circuit and/or the touch sensing circuit. The power supply circuit can supply various voltages and power voltages related to display driving to the display driving circuit or display panel 110.

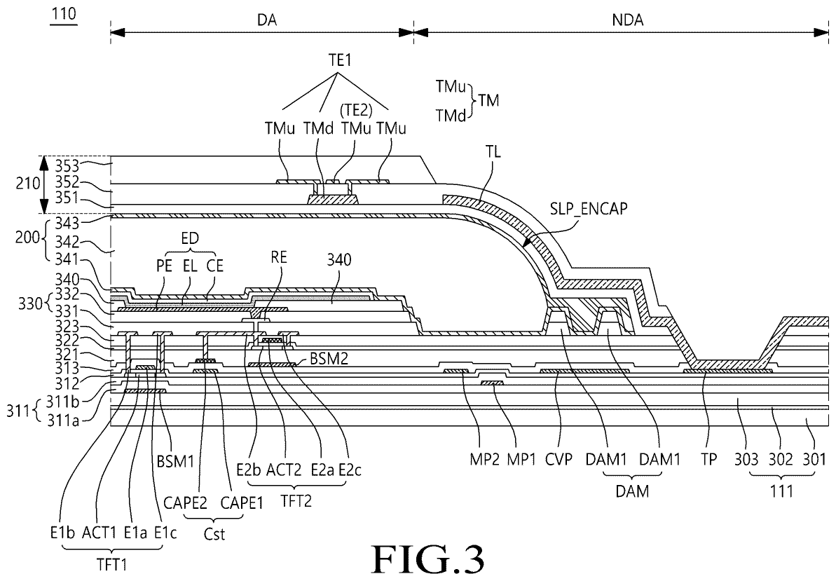

Next, FIG. 3 is a cross-sectional view of a display panel 110 according to embodiments of the disclosure. Referring to FIG. 3, the display panel 110 includes a substrate 111, a transistor unit, a light emitting element unit, and an encapsulation unit, but embodiments of the disclosure are not limited thereto.

In addition, the substrate 111 can be a single layer or multiple layers. When the substrate 111 includes multiple layers, the substrate 111 can include a first substrate 301, an intermediate substrate layer 302, and a second substrate 303. As shown, the intermediate substrate layer 302 is positioned between the first substrate 301 and the second substrate 303. For example, each of the first substrate 301 and the second substrate 303 can be a polyimide (PI) layer, and the intermediate substrate layer 302 can be an inorganic insulation layer, but embodiments of the disclosure are not limited thereto. When an electric charge is charged to the first substrate PII which is a polyimide layer, the intermediate substrate layer 302 can prevent the electric charge from affecting transistors disposed on the second substrate 303 through the second substrate 303 which is a polyimide layer.

Further, the intermediate substrate layer 302 can prevent a moisture component from penetrating upward through the first substrate 301. For example, the intermediate substrate layer 302 can be formed of a single layer of silicon nitride (SiNₓ) or silicon oxide (SiOₓ) or multiple layers thereof, or can be formed of a double layer of silicon dioxide (SiO₂) and silicon nitride (SiNₓ), but is not limited thereto.

In addition, as shown in FIG. 3, the transistor unit can include an insulation layer 311, 312, 313, 321, 322, and 323 on the substrate 111, thin film transistors TFT1 and TFT2, a storage capacitor Cst, and various electrodes or signal lines. Also, the thin film transistors TFT1 and TFT2 included in the transistor unit can include a first thin film transistor TFT1 and a second thin film transistor TFT2. Further, the first thin film transistor TFT1 can include a first active layer ACT1, a first electrode Ela, a second electrode E1b, and a third electrode E1c.

Also, the first electrode Ela can be a gate electrode, the second electrode E1b can be a source electrode or a drain electrode, and the third electrode E1c can be a drain electrode or a source electrode. Hereinafter, for convenience, the first electrode Ela is referred to as a first gate electrode Ela, the second electrode E1b is referred to as a first source electrode E1b, and the third electrode E1c is referred to as a first drain electrode E1c. However, embodiments of the disclosure are not limited thereto.

In addition, the first active layer ACT1 can include a first semiconductor material. For example, the first semiconductor material can include an oxide semiconductor, amorphous silicon, polysilicon, or low temperature polysilicon (LTPS), but embodiments of the disclosure are not limited thereto. Also, the first thin film transistor TFT1 can be implemented as a p-channel transistor or an n-channel thin film transistor, but embodiments of the disclosure are not limited thereto.

In addition, the second thin film transistor TFT2 can include a second active layer ACT2, a fourth electrode E2a, a fifth electrode E2b, and a sixth electrode E2c. Also, the fourth electrode E2a can be a gate electrode, the fifth electrode E2b can be a source electrode or a drain electrode, and the sixth electrode E2c can be a drain electrode or a source electrode. Hereinafter, for convenience, the fourth electrode E2a is referred to as a second gate electrode E2a, the fifth electrode E2b is referred to as a second source electrode E2b, and the sixth electrode E2c is referred to as a second drain electrode E2c. However, embodiments of the disclosure are not limited thereto.

In addition, the second active layer ACT2 can include a second semiconductor material. For example, the second semiconductor material can include an oxide semiconductor, amorphous silicon, polysilicon, or low temperature polysilicon (LTPS), but embodiments of the disclosure are not limited thereto. The second thin film transistor TFT2 can be implemented as a p-channel transistor or an n-channel thin film transistor, but embodiments of the disclosure are not limited thereto.

Also, the type of the semiconductor material of each of the first active layer ACT1 of the first thin film transistor TFT1 and the second active layer ACT2 of the second thin film transistor TFT2 can be as follows. For example, the first active layer ACT1 of the first thin film transistor TFT1 and the second active layer ACT2 of the second thin film transistor TFT2 can include an oxide semiconductor material. As another example, the first active layer ACT1 of the first thin film transistor TFT1 and the second active layer ACT2 of the second thin film transistor TFT2 can include a low-temperature polysilicon semiconductor material. As still another example, the first active layer ACT1 of the first thin film transistor TFT1 can include a low-temperature polysilicon semiconductor material, and the second active layer ACT2 of the second thin film transistor TFT2 can include an oxide semiconductor material. Also, the first active layer ACT1 of the first thin film transistor TFT1 can include an oxide semiconductor material, and the second active layer ACT2 of the second thin film transistor TFT2 can include a low-temperature polysilicon semiconductor material.

In addition, the purposes of the transistors in the display area DA are as follows. For example, all of the transistors in each subpixel SP can be implemented as first thin film transistors TFT1. As another example, all of the transistors in each subpixel SP can be implemented as second thin film transistors TFT2. Also, some of the transistors in each subpixel SP can be implemented as first thin film transistors TFT1, and the other the transistors can be implemented as second thin film transistors TFT2. In other words, each subpixel SP can include at least one first thin film transistor TFT1 and at least one second thin film transistor TFT2.

When some of the transistors in each subpixel SP are implemented as first thin film transistors TFT1 and the others are implemented as second thin film transistors TFT2, the following examples is possible. For example, in each subpixel SP, the driving transistor DT can be implemented as a first thin film transistor TFT1, and other transistors (e.g., the scan transistor ST, the emission control transistor, etc.) than the driving transistor DT can be implemented as second thin film transistors TFT2. As another example, in each subpixel SP, the driving transistor DT can be implemented as a second thin film transistor TFT2, and other transistors (e.g., the scan transistor ST, the emission control transistor, etc.) than the driving transistor DT can be implemented as first thin film transistors TFT1.

In FIG. 3, the second thin film transistor TFT2 connected to the pixel electrode PE of the light emitting element ED can be a driving transistor DT or a transistor different from the driving transistor DT according to the configuration of the subpixel circuit SPC. For example, in FIG. 3, the second thin film transistor TFT2 connected to the pixel electrode PE of the light emitting element ED can be an emission control transistor connected between the driving transistor DT and the light emitting element ED.

The purposes of the transistors in the non-display area NDA is as follows. For example, the active layers of the transistors included in the gate-in-panel (GIP) type gate driving circuit 130 can be formed of an oxide semiconductor material. As another example, the active layers of the transistors included in the gate-in-panel (GIP) type gate driving circuit 130 can be formed of a low-temperature polysilicon semiconductor material. As still another example, among the transistors included in the gate-in-panel (GIP) type gate driving circuit 130, some active layers can be formed of a low-temperature polysilicon semiconductor material, and other active layers can be formed of an oxide semiconductor material.

Further, the second active layer ACT2 of the second thin film transistor TFT2 can be positioned higher from the substrate 111 than the first active layer ACT1 of the first thin film transistor TFT1. Also, the first buffer layer 311 can be disposed under the first active layer ACT1 of the first thin film transistor TFT1, and a second buffer layer 321 can be disposed under the second active layer ACT2 of the second thin film transistor TFT2. For example, the first active layer ACT1 of the first thin film transistor TFT1 can be positioned on the first buffer layer 311, and the second active layer ACT2 of the second thin film transistor TFT2 can be positioned on the second buffer layer 321. The second buffer layer 321 can be positioned higher than the first buffer layer 311.

Also, the storage capacitor Cst can be disposed in various metal layers in the display panel 110. For example, the storage capacitor Cst can include a first capacitor electrode CAPE1 and a second capacitor CAPE2.

In addition, the light emitting element portion can include a plurality of light emitting elements ED disposed on the planarization layer 330. Each of the light emitting elements ED can include a pixel electrode PE, an intermediate layer EL, and a common electrode CE.

Hereinafter, a structure or a vertical structure of the display panel 110 according to embodiments of the disclosure is described in more detail with reference to FIG. 3. Referring to FIG. 3, the first buffer layer 311 can be disposed on the substrate 111. The first buffer layer 311 can be a single layer or multiple layers, but embodiments of the disclosure are not limited thereto. When the first buffer layer 311 includes multiple layers, the first buffer layer 311 can include a lower buffer layer 311a and an upper buffer layer 311b.

Also, the first active layer ACT1 of the first thin film transistor TFT1 can be disposed on the first buffer layer 311. The first active layer ACT1 can include a channel area in which a channel is formed, a source connection area on one side of the channel area, and a drain connection area on the other side of the channel area.

In addition, the first gate insulation layer 312 can be disposed on the first active layer ACT1 of the first thin film transistor TFT1. Also, the first gate electrode Ela of the first thin film transistor TFT1 can be disposed on the first gate insulation layer 312, and the first inter-layer insulation layer 313 can be disposed on the first gate electrode Ela of the first thin film transistor TFT1. Here, the metal layer where the first gate electrode Ela of the first thin film transistor TFT1 is disposed can be referred to as a gate metal layer.

In addition, the second buffer layer 321 can be disposed on the first inter-layer insulation layer 313. The second active layer ACT2 of the second thin film transistor TFT2 can be disposed on the second buffer layer 321. Also, the second active layer ACT2 can include a channel area in which a channel is formed, a source connection area on one side of the channel area, and a drain connection area on the other side of the channel area.

Further, the second gate insulation layer 322 can be disposed on the second active layer ACT2 of the second thin film transistor TFT2. The second gate electrode E2a of the second thin film transistor TFT2 can be disposed on the second gate insulation layer 322. Also, the second inter-layer insulation layer 323 can be disposed on the second gate electrode E2a of the second thin film transistor TFT2. Here, the second gate electrode E2a of the second thin film transistor TFT2 can be referred to as a second gate metal layer.

In addition, the first source electrode E1b and the first drain electrode E1c of the first thin film transistor TFT1, and the second source electrode E2b and the second drain electrode E2c of the second thin film transistor TFT2 can be disposed on the second interlayer insulation layer 323. Further, the first source electrode E1b and the first drain electrode E1c of the first thin film transistor TFT1 can be connected to the source connection area and the drain connection area, respectively, of the first active layer ACT1 through holes of the second inter-layer insulation layer 323, the second gate insulation layer 322, the second buffer layer 321, the first inter-layer insulation layer 313, and the first gate insulation layer 312.

In addition, the second source electrode E2b and the second drain electrode E2c of the second thin film transistor TFT2 can be connected to the source connection area and the drain connection area, respectively, of the second active layer ACT2 through the holes of the second inter-layer insulation layer 323 and the second gate insulation layer 322. Further, the first source electrode E1b and the first drain electrode E1c of the first thin film transistor TFT1, and the second source electrode E2b and the second drain electrode E2c of the second thin film transistor TFT2 can include a first source-drain metal and can be disposed in the first source-drain metal layer.

Referring to FIG. 3, e.g., the storage capacitor Cst can be formed by a first capacitor electrode CAPE1 and a second capacitor electrode CAPE2. In some instances, the storage capacitor Cst can be formed by three or more capacitor electrodes, or can have a form in which two or more capacitors are connected in parallel. Each of the first capacitor electrode CAPE1 and the second capacitor electrode CAPE2 can be disposed on various metal layers disposed in the display panel 110.

For example, the first capacitor electrode CAPE1 can include the same first gate metal as the first gate electrode Ela of the first thin film transistor TFT1 on the first gate insulation layer 312 and can be disposed in the first gate metal layer, but embodiments of the disclosure are not limited thereto. Also, the second capacitor electrode CAPE2 can be disposed on the first inter-layer insulation layer 313.

In addition, the second source electrode E2b of the second thin film transistor TFT2 can be electrically connected to the second capacitor electrode CAPE2 through holes of the second inter-layer insulation layer 323, the second gate insulation layer 322, and the second buffer layer 321. For example, when the subpixel SP is configured as shown in FIG. 2, the first thin film transistor TFT1 can be the scanning transistor ST of FIG. 2, and the second thin film transistor TFT2 can be the driving transistor DT of FIG. 2.

The transistor unit can further include at least one additional metal pattern MP1 and MP2. For example, the first metal pattern MP1 can be disposed between the lower buffer layer 311a and the upper buffer layer 311b included in the first buffer layer 311, but embodiments of the disclosure are not limited thereto. The second metal pattern MP2 can include the same first gate metal as the first gate electrode Ela of the first thin film transistor TFT1, and can be disposed in the first gate metal layer, but embodiments of the disclosure are not limited thereto. Each of the first metal pattern MP1 and the second metal pattern MP2 can be disposed in the display area DA or the non-display area NDA.

Referring to FIG. 3, the transistor unit can further include a first shield pattern BSM1 disposed on the substrate 111. In particular, the first shield pattern BSM1 can overlap the first active layer ACT1 and be disposed under the first active layer ACT1 of the first thin film transistor TFT1. For example, the first shield pattern BSM1 can be disposed between the substrate 111 and the first buffer layer 311, or can be disposed between the lower buffer layer 311a and the upper buffer layer 311b.

The transistor unit can further include a second shield pattern BSM2 disposed on the substrate 111. In particular, the second shield pattern BSM2 can overlap the second active layer ACT2 and be disposed under the second active layer ACT2 of the second thin film transistor TFT2. For example, the second shield pattern BSM2 can be disposed in a metal layer between the first insulation layer 313 and the second buffer layer 321. The second shield pattern BSM2 can be disposed in the same metal layer as the second capacitor CAPE2, but embodiments of the disclosure are not limited thereto. As another example, the second shield pattern BSM2 can be disposed in the same first gate metal layer as the first gate electrode Ela of the first thin film transistor TFT1.

Referring to FIG. 3, the transistor unit can further include a common driving signal layer CVP to which a common driving signal is applied. In particular, the common driving signal layer CVP can be disposed in the display area DA or the non-display area NDA. For example, the common driving signal applied to a common driving signal layer CVP can also be referred to as a power signal and can include at least one of a driving voltage VDD and a base voltage VSS. The driving voltage VDD can be referred to as a high-potential driving voltage (a high-potential power supply voltage or a high-potential voltage), and the base voltage VSS can be referred to as a low-potential driving voltage (a low-potential power supply voltage or a low-potential voltage).

In addition, the planarization layer 330 can be disposed on the first thin film transistor TFT1 and the second thin film transistor TFT2, and can be disposed under the light emitting element ED. The planarization layer 330 can be an organic insulation layer including an organic insulating material.

For example, the planarization layer 330 can be constituted of one layer. As another example, the planarization layer 330 can include two layers. In particular, the planarization layer 330 can include a first planarization layer 331 and a second planarization layer 332. As another example, the planarization layer 330 can include three or more layers. Embodiments of the disclosure are not limited thereto.

Referring to FIG. 3, the first planarization layer 331 can be disposed on the first source electrode E1b and the first drain electrode E1c of the first thin film transistor TFT1, and the second source electrode E2b and the second drain electrode E2c of the second thin film transistor TFT2. For example, the first planarization layer 331 can be disposed on the first thin film transistor TFT1 and the second thin film transistor TFT2. Also, the first planarization layer 331 can be disposed while covering both the first thin film transistor TFT1 and the second thin film transistor TFT2.

Referring to FIG. 3, a connection electrode RE can be disposed on the first planarization layer 331. In particular, the connection electrode RE can electrically connect the second source electrode E2b of the second thin film transistor TFT2 and the pixel electrode PE. Further, the connection electrode RE can be electrically connected to the second source electrode E2b of the second thin film transistor TFT2 through the hole of the first planarization layer 331. The second source electrode E2b of the second thin film transistor TFT2 can be electrically connected to the second capacitor electrode CAPE2 of the storage capacitor Cst.

In addition, the connection electrode RE can be disposed in the second source-drain metal layer on the first planarization layer 331 and can include a second source-drain metal. Also, the second planarization layer 332 can be disposed on the connection electrode RE.

Referring to FIG. 3, the light emitting element unit can be disposed on the second planarization layer 332. In particular, the light emitting element ED can be formed on the second planarization layer 332 and include a pixel electrode PE, an intermediate layer EL, and a common electrode CE. Further, the emission area of the light emitting element ED can be formed in an area in which the pixel electrode PE, the intermediate layer EL, and the common electrode CE overlap and contact each other. In addition, the pixel electrode PE can be disposed on the second planarization layer 332 and be electrically connected to the connection electrode RE through the hole of the second planarization layer 332.

As shown in FIG. 3, a bank 340 can be disposed on the pixel electrode PE. The opening of the bank 340 can expose a portion of the pixel electrode PE to form the emission area and can overlap a portion of the pixel electrode PE.

For example, the bank 340 can be formed of a material including a black pigment, or an organic material such as a benzocyclobutene resin, a polyimide resin, an acrylic resin, or a photosensitive polymer, but embodiments of the disclosure are not limited thereto. When the bank 340 is formed of a material including a black pigment, a black dye, or the like, the bank can be a black bank. When the bank 340 is formed of a material including a black pigment or a black dye, light from the outside can be blocked or light reflected from the outside can be blocked, and thus the luminance of the touch display device 100 can be further enhanced. Further, the intermediate layer EL of the light emitting element ED can be disposed on a portion of the pixel electrode PE and the bank 340, and the common electrode CE can be disposed on the intermediate layer EL.

Referring to FIG. 3, the encapsulation unit can be disposed on the light emitting element unit and can be positioned on the common electrode CE. As shown, the encapsulation unit can include the encapsulation layer 200 formed on the common electrode CE.

In more detail, the encapsulation layer 200 can prevent moisture or oxygen from penetrating into the light emitting element ED. For example, the encapsulation layer 200 can prevent moisture or oxygen from penetrating into the organic material included in the intermediate layer EL of the light emitting element ED. The encapsulation layer 200 can also be formed of a single layer or multiple layers, but embodiments of the disclosure are not limited thereto.

For example, the encapsulation layer 200 can include a first encapsulation layer 341, a second encapsulation layer 342, and a third encapsulation layer 343, but embodiments of the disclosure are not limited thereto. Also, the first encapsulation layer 341 and the third encapsulation layer 343 can include an inorganic layer, and the second encapsulation layer 342 can include an organic layer, but embodiments of the disclosure are not limited thereto. In addition, the second encapsulation layer 342 can also be referred to as a particle cover layer (PCL) and include, e.g., a silicon oxycarbon (SiOCz), an acrylic or epoxy resin.

That is, the encapsulation unit can include the encapsulation layer 200 on the plurality of light emitting elements ED. Also, the encapsulation layer 200 can be a single layer or multiple layers, but embodiments of the disclosure are not limited thereto. In addition to the encapsulation layer 200, the encapsulation unit can further include a dam structure DAM for preventing a material constituting the encapsulation layer 200 from overflowing. In particular, when the second encapsulation layer 342 included in the encapsulation layer 200 is an organic encapsulation layer formed of an organic material, the dam structure DAM can prevent the second encapsulation layer 342 including the organic material from overflowing.

For example, as shown in FIG. 3, the dam structure DAM can include a first dam DAM1 disposed near an edge of the second encapsulation layer 342 and a second dam DAM2 disposed further outside the first dam DAM1.

Also, the display panel 110 according to embodiments of the disclosure can include a touch sensor. In FIG. 3, the display panel 110 according to embodiments of the disclosure can include a touch sensor layer 210 disposed on the encapsulation layer 200 and having a touch sensor.

Referring to FIG. 3, the touch sensor layer 210 can include a plurality of touch electrodes TE corresponding to touch sensors, and can include at least one touch metal layer for forming the plurality of touch electrodes TE. For example, the touch sensor layer 210 can include touch metal layers where the touch metals TM are disposed to form the touch electrodes TE. The touch metal layers can include a lower touch metal layer where lower touch metals TMd are disposed, and an upper touch metal layer where upper touch metals TMu are disposed. In this instance, the touch sensor layer 210 can further include a touch interlayer insulation layer 352 disposed between the lower touch metal layer and the upper touch metal layer.

Also, one of the lower touch metal layer and the upper touch metal layer can be a sensor metal layer and the other can be a bridge metal layer. Further, the lower touch metal layer can be a bridge metal layer, and the upper touch metal layer can be a sensor metal layer. In this instance, the upper touch metals TMu disposed in the upper touch metal layer can be sensor metals that form touch sensors, and the lower touch metals TMd disposed in the lower touch metal layer can be bridge metals that electrically connect the upper touch metals TMu, which are sensor metals. For example, two or more upper touch metals TMu and at least one lower touch metal TMd can constitute one first touch electrode TE1. In this instance, two or more upper touch metals TE2 can be electrically connected by at least one lower touch metal TMd.

As another example, the lower touch metal layer can be a sensor metal layer, and the upper touch metal layer can be a bridge metal layer. In this instance, the lower touch metals TMd disposed in the lower touch metal layer can be sensor metals that form touch sensors, and the upper touch metals TMu disposed in the upper touch metal layer can be bridge metals that electrically connect the lower touch metals TMd, which are sensor metals.

As another example, each of the lower touch metal layer and the upper touch metal layer can be a sensor metal layer and a bridge metal layer. For example, the lower touch metal layer can be a sensor metal layer and a bridge metal layer, and the upper touch metal layer can be a sensor metal layer and a bridge metal layer. In this instance, the lower touch metals TMd disposed in the lower touch metal layer can include sensor metals and bridge metals, and the upper touch metals TMu disposed in the upper touch metal layer can include sensor metals and bridge metals.

Referring to FIG. 3, the touch sensor layer 210 can further include a touch buffer layer 351 disposed on the encapsulation layer 200. In particular, the touch buffer layer 351 can be disposed between the encapsulation layer 200 and the touch metal layer. For example, the lower touch metal layer can be disposed on the touch buffer layer 351, and the touch interlayer insulation layer 352 can be disposed on the lower touch metal layer.

Referring to FIG. 3, the touch sensor layer 210 can further include a touch protection layer 353 disposed to cover the touch metal layer. For example, the touch protection layer 353 can be disposed on the upper touch metal layer. In addition, the touch buffer layer 351 can be an inorganic layer including an inorganic insulating material or an organic layer including an organic insulating material, the touch interlayer insulation layer 352 can be an inorganic layer including an inorganic insulating material or an organic layer including an organic insulating material, and the touch protection layer 353 can be an inorganic layer including an inorganic insulating material or an organic layer including an organic insulating material.

Also, at least one of the touch buffer layer 351 and the touch interlayer insulation layer 352 can extend from the display area DA to the non-display area NDA. Further, the touch protection layer 353 can be disposed to extend from the display area DA to the non-display area NDA.

As shown in FIG. 3, the touch routing line TL can electrically connect the touch electrode TE and the touch pad TP. The touch routing line TL can be formed of at least one of the lower touch metal TMd and the upper touch metal TMu. For example, the touch routing line TL can be formed of the lower touch metal TMd, or the touch routing line TL can be formed of the upper touch metal TMu, or the lower touch metal TMd and the upper touch metal TMu. When one touch routing line TL is formed of the lower touch metal TMd and the upper touch metal TMu, the lower touch metal TMd and the upper touch metal TMu constituting one touch routing line TL can be electrically connected through a hole in the insulation layer 352.

In addition, one touch routing line TL can include a plurality of wiring sections, and each of the plurality of wiring sections can be a single wiring section or a double wiring section. Here, the single wiring section can be a wiring section having one signal path, and the double wiring section can be a wiring section where two signal paths are connected in parallel. Also, the touch routing line TL can be disposed along the inclined surface SLP_ENCAP of the encapsulation layer 200, and can extend to the touch pad TP through the upper portion of the dam DAM.

In addition, the touch buffer layer 351 can have an opening exposing at least a portion of the touch pad TP, and the touch routing line TL can be electrically connected to the touch pad TP through the opening of the touch buffer layer 351. Further, the touch interlayer insulation layer 352 can be disposed on the touch routing line TL, and can extend to an area where the touch pad TP is disposed. The touch protection layer 353 can be disposed only in the display area DA, or can extend to the non-display area NDA to be disposed on the touch routing line TL. In some instances, the touch protection layer 353 can further extend to the upper portion of the touch pad TP.

Each of the plurality of touch electrodes TE can be a mesh-type electrode having a plurality of openings. In this instance, each of the plurality of touch electrodes TE can be formed of at least one upper touch metal TMu. However, embodiments of the disclosure are not limited thereto.

For example, the plurality of touch electrodes TE can include a first touch electrode TE1 and a second touch electrode TE2. When the lower touch metal layer is a bridge metal layer and the upper touch metal layer is a sensor metal layer, two or more upper touch metals TMu forming the first touch electrode TE1 corresponding to the touch sensor can be electrically connected through at least one lower touch metal TMd, which is bridge metals. Also, the two upper touch metals TMu spaced apart from each other can be electrically connected by the lower touch metal TMd to constitute one first touch electrode TE1.

Referring to FIG. 3, the lower touch metals TMd and upper touch metals TMu can be disposed not to overlap the light emitting element ED. The lower touch metals TMd and the upper touch metals TMu can also overlap the bank 340. Accordingly, the luminous efficiency of the light emitting element ED can increase.

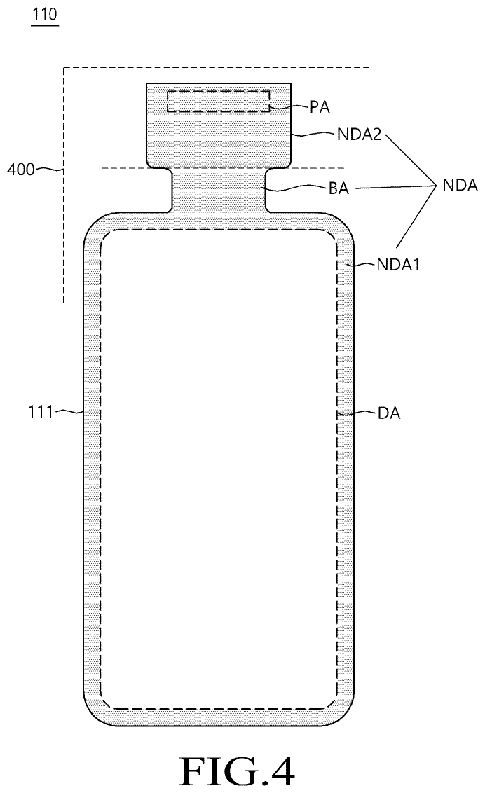

Next, FIG. 4 is a plan view of a display panel 110 according to embodiments of the disclosure. Referring to FIG. 4, the substrate 111 of the display panel 110 includes a display area DA and a non-display area NDA. The display area DA and the non-display area NDA are areas of the display panel 110.

As described above, the display area DA is an area where an image is displayed, and incudes a plurality of subpixels SP. Also, the non-display area NDA is where an image is not displayed, and can be an area except for the display area DA. In addition, the subpixel SP is not disposed in the non-display area NDA. However, at least one dummy subpixel that is not directly involved in image display can be disposed in the non-display area NDA.

As shown in FIG. 4, the non-display area NDA can include a first non-display area NDA1, a bending area BA, and a second non-display area NDA2. The first non-display area NDA1 can be positioned around the display area DA, and can be an area closest to the display area DA among the first non-display area NDA1, the bending area BA, and the second non-display area NDA2.

In addition, the second non-display area NDA2 can include a pad area PA where various pads are disposed, and can be an area farthest from the display area DA among the first non-display area NDA1, the bending area BA, and the second non-display area NDA2. The bending area BA is an area where the substrate 111 is bent, and can be an area positioned between the first non-display area NDA1 and the second non-display area NDA2.

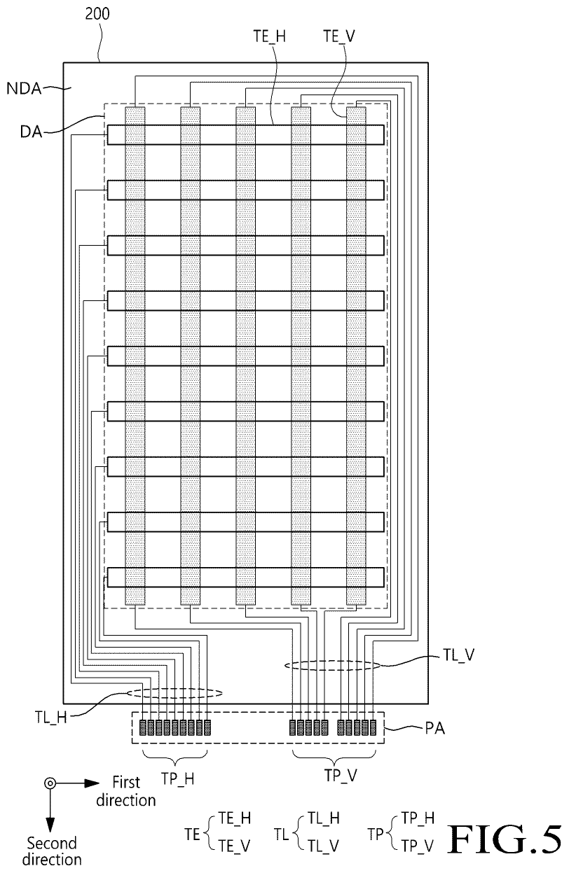

Next, FIG. 5 is a view illustrating a touch sensor structure of a touch display device 100 according to embodiments of the disclosure. Referring to FIG. 5, the display panel 110 of the touch display device 100 includes a substrate 111 including a display area DA and a non-display area NDA around the display area DA, a plurality of touch electrodes TE disposed on the substrate 111 and positioned in the display area DA, a plurality of touch pads TP disposed on the substrate 111 and positioned in the non-display area NDA, and a plurality of touch routing lines TL electrically connecting the touch electrodes TE and the touch pads TP.

Further, the touch sensor can include a plurality of touch electrodes TE including horizontal touch electrodes TE_H and vertical touch electrodes TE_V.

As shown in FIG. 5, the touch electrodes TE can be disposed in the display area DA and can be positioned on the encapsulation layer 200. Also, each of the horizontal touch electrodes TE_H can be disposed in a first direction, and each of the vertical touch electrodes TE_V can be disposed in a second direction different from the first direction.

In the disclosure, the first direction and the second direction can be relatively different directions. As an example, the first direction can be the x-axis direction, and the second direction can be the y-axis direction. In contrast, the first direction can be the y-axis direction, and the second direction can be the x-axis direction. The first direction and the second direction may be, or may not be, perpendicular to each other. In the disclosure, row and column are relative terms, and from a point of view, the terms “row” and “column” can be interchangeably used. For example, the first direction can be a direction in which the gate line GL extends, and the second direction can be a direction in which the data line DL extends. As another example, the first direction can be a direction in which the data line DL extends, and the second direction can be a direction in which the gate line GL extends.

In addition, each of the horizontal touch electrodes TE_H and vertical touch electrodes TE_V can be one touch electrode having a bar shape. In this instance, e.g., the horizontal touch electrodes TE_H can be disposed in the lower touch metal layer, and the vertical touch electrodes TE_V can be disposed in the upper touch metal layer. As another example, the horizontal touch electrodes TE_H can be disposed in the upper touch metal layer, and the vertical touch electrodes TE_V can be disposed in the lower touch metal layer.

As another example, each of the horizontal touch electrodes TE_H can be configured with a plurality of horizontal touch electrodes and a plurality of horizontal bridge electrodes electrically connecting the horizontal touch electrodes. Also, each of the vertical touch electrodes TE_V can be configured with a plurality of vertical touch electrodes and a plurality of vertical bridge electrodes electrically connecting the vertical touch electrodes. In this instance, e.g., each of the horizontal touch electrodes and the vertical touch electrodes can be disposed in the upper touch metal layer, and each of the horizontal bridge electrodes and the vertical bridge electrodes can be disposed in the lower touch metal layer.

Roles (functions) of the horizontal touch electrodes TE_H and the vertical touch electrodes TE_V can be distinguished. For example, the horizontal touch electrodes TE_H can be driving electrodes (or transmitting electrodes) to which a touch driving signal is applied by the touch driving circuit 220, and the vertical touch electrodes TE_V can be sensing electrodes (or receiving electrodes) sensed by the touch driving circuit 220. In this instance, each of the horizontal touch electrodes TE_H can be referred to as a driving touch electrode (or a transmitting touch electrode), and each of the vertical touch electrodes TE_V can be referred to as a sensing touch electrode (or a receiving touch electrode).

As another example, the vertical touch electrodes TE_V can be driving electrodes (or transmitting electrodes) to which a touch driving signal is applied by the touch driving circuit 220, and the horizontal touch electrodes TE_H can be sensing electrodes (or receiving electrodes) sensed by the touch driving circuit 220. In this instance, each of the vertical touch electrodes TE_V can be referred to as a driving touch electrode (or a transmitting touch electrode), and each of the horizontal touch electrodes TE_H can be referred to as a sensing touch electrode (or a receiving touch electrode).

Referring to FIG. 5, the touch sensor structure can further include a plurality of touch routing lines TL including a plurality of horizontal touch routing lines TL_H and a plurality of vertical touch routing lines TL_V. The touch routing lines TL can be disposed in the non-display area NDA, and a portion (e.g., a portion connected to the touch electrode) of at least one of the touch routing lines TL can be positioned in the display area DA.

Also, the touch sensor structure can further include a plurality of touch pads TP including a plurality of horizontal touch pads TP_H and a plurality of vertical touch pads TP_V. The touch pads TP can be disposed in the non-display area NDA.

Further, the horizontal touch routing lines TL_H can electrically connect the horizontal touch electrodes TE_H and the horizontal touch pads TP_H. Also, the vertical touch routing lines TL_V can electrically connect the vertical touch electrodes TE_V and the vertical touch pads TP_V.

One horizontal touch routing line TL_H can be connected to each of the horizontal touch electrodes TE_H or two or more horizontal touch routing lines TL_H can be connected thereto. One vertical touch routing line TL_V can be connected to each of the vertical touch electrodes TE_V or two or more vertical touch routing lines TL_V can be connected thereto.

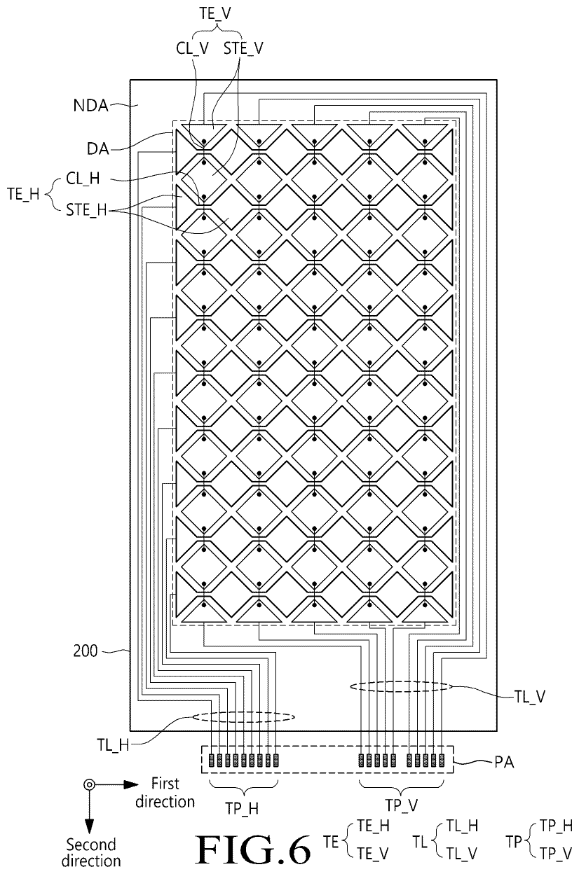

Next, FIG. 6 illustrates another touch sensor structure of a touch display device 100 according to embodiments of the disclosure. Referring to FIG. 6, a touch sensor according to embodiments of the disclosure can include a plurality of touch electrodes TE disposed in the display area DA and can be disposed on the encapsulation layer 200. As shown, the touch electrodes TE can include a plurality of horizontal touch electrodes TE_H and a plurality of vertical touch electrodes TE_V.

Further, each of the horizontal touch electrodes TE_H can include two or more horizontal sub touch electrodes STE_H disposed in the same row (or column) and one or more horizontal bridge electrodes CL_H electrically connecting them. In the example of FIG. 6, two or more horizontal sub touch electrodes STE_H and one or more horizontal bridge electrodes CL_H constituting one horizontal touch electrode TE_H can be an integrated touch metal (e.g., upper touch metal). as Also, in the example of FIG. 6, two or more horizontal sub touch electrodes STE_H can be disposed in the upper touch metal layer, and one or more horizontal bridge electrodes CL_H can be disposed in the lower touch metal layer.

Each of the vertical touch electrodes TE_V can include two or more vertical sub touch electrodes STE_V disposed in the same column (or row) and one or more vertical bridge electrodes CL_V electrically connecting them. For example, two or more vertical sub touch electrodes STE_V and one or more vertical bridge electrodes CL_V constituting one vertical touch electrode TE_V can be an integrated touch metal (e.g., upper touch metal). As another example, as in the example of FIG. 6, two or more vertical sub touch electrodes STE_V can be disposed in the upper touch metal layer, and one or more vertical bridge electrodes CL_V can be disposed in the lower touch metal layer.

In an area (a touch electrode crossing area) where the horizontal touch electrode TE_H and the vertical touch electrode TE_V cross each other, the horizontal bridge electrode CL_H and the vertical bridge electrode CL_V can cross each other. When the horizontal bridge electrode CL_H and the vertical bridge electrode CL_V cross each other in the touch electrode crossing area, the horizontal bridge electrode CL_H and the vertical bridge electrode CL_V should be positioned in different layers.

Therefore, to cross the horizontal touch electrodes TE_H and the vertical touch electrodes TE_V, the horizontal sub touch electrodes STE_H, the vertical sub touch electrodes STE_V, the vertical touch electrodes TE_V, and the vertical bridge electrodes CL_V can be positioned in two or more layers.

Referring to FIG. 6, the touch sensor structure according to embodiments of the disclosure can further include a plurality of touch routing lines TL including a plurality of horizontal touch routing lines TL_H and a plurality of vertical touch routing lines TL_V. The touch routing lines TL can be disposed in the non-display area NDA. A portion (e.g., a portion connected to the touch electrode) of at least one of the touch routing lines TL can be positioned in the display area DA.

In addition, the touch sensor structure according to embodiments of the disclosure can further include a plurality of touch pads TP. The touch pads TP can include a plurality of horizontal touch pads TP_H and a plurality of vertical touch pads TP_V. The touch pads TP can also be disposed in the non-display area NDA.

Referring to FIG. 6, each of the horizontal touch electrodes TE_H can be electrically connected to the corresponding horizontal touch pad TP_H through one or more horizontal touch routing lines TL_H. At least one of the two horizontal sub touch electrodes STE_H disposed at two opposite outermost sides among the two or more horizontal sub touch electrodes STE_H included in one horizontal touch electrode TE_H can be electrically connected to the corresponding horizontal touch pad TP_H through the horizontal touch routing line TL_H.

Also, each of the vertical touch electrodes TE_V can be electrically connected to the corresponding vertical touch pad TP_V through one or more vertical touch routing lines TL_V. In other words, at least one of the two vertical sub touch electrodes STE_V disposed on two opposite outermost sides among the two or more vertical sub touch electrodes STE_V included in one vertical touch electrode TE_V can be electrically connected to the corresponding vertical touch pad TP_V through the vertical touch routing line TL_V.

Meanwhile, as illustrated in FIG. 6, the horizontal touch electrodes TE_H and the vertical touch electrodes TE_V can be disposed on the encapsulation layer 200. The horizontal sub touch electrodes STE_H and the horizontal bridge electrodes CL_H constituting the horizontal touch electrodes TE_H can be disposed on the encapsulation layer 200. The vertical sub touch electrodes STE_V and the vertical bridge electrodes CL_V constituting the vertical touch electrodes TE_V can be disposed on the encapsulation layer 200.

Also, each of the horizontal touch routing lines TL_H can be disposed on the encapsulation layer 200 and extend to the outside of the encapsulation layer 200 to be electrically connected to the horizontal touch pads TP_H in the pad area PA positioned outside the encapsulation layer 200. Further, each of the vertical touch routing lines TL_V can be disposed on the encapsulation layer 200 and extend to the outside of the encapsulation layer 200 to be electrically connected to the vertical touch pads TP_V in the pad area PA positioned outside the encapsulation layer 200. In addition, the encapsulation layer 200 can be positioned in the display area DA, and in some instances, can extend to the non-display area NDA.

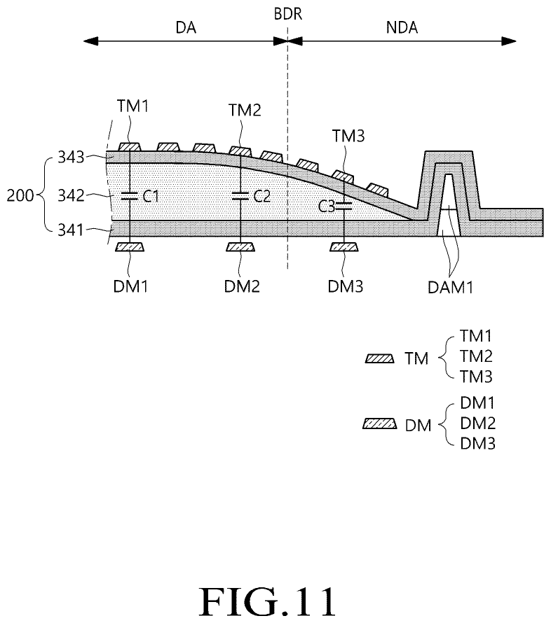

Meanwhile, as described above, the encapsulation layer 200 can protect the organic layer of the organic light emitting device from physical impact, oxygen, and/or moisture in the process of manufacturing the organic light emitting element ED, which is a light emitting element based on an organic material, used in, e.g., TVs, computers, and mobile communication devices. Recently, the encapsulation layer 200 has been developed to be applicable to flexible electronic devices. For example, the encapsulation layer 200 can have a thin film encapsulation (TFE) structure where organic layers having flexible properties and inorganic layers having excellent mechanical properties are alternately stacked. For example, the encapsulation layer 200 can include a first encapsulation layer 341, a second encapsulation layer 342, and a third encapsulation layer 343 (FIG. 11). Each of the first encapsulation layer 341 and the third encapsulation layer 343 is an inorganic layer, and the second encapsulation layer 342 can be disposed between the first encapsulation layer 341 and the third encapsulation layer 343, and can be an organic layer.

For example, each of the first encapsulation layer 341, the second encapsulation layer 342, and the third encapsulation layer 343 can be formed through a deposition process. As another example, among the first encapsulation layer 341, the second encapsulation layer 342, and the third encapsulation layer 343, the first encapsulation layer 341 and the third encapsulation layer 343, which are inorganic layers, can be formed through a deposition process, and the second encapsulation layer 342 which is an organic layer can be formed through an inkjet printing process.

The inkjet printing process includes a method for finely spraying a coating composition (organic material) onto a desired portion through a nozzle and forming a film (the second encapsulation layer 342). The inkjet printing process can be advantageous for mass production or large-sized panel manufacturing because it uses a multi-head where multiple nozzles are connected. Further, when the second encapsulation layer 342 is formed through the inkjet printing process, fast, economical, and eco-friendly manufacturing is possible. The composition can be configured to meet a predetermined viscosity and surface energy (tension) so as to be applied to inkjet printing.

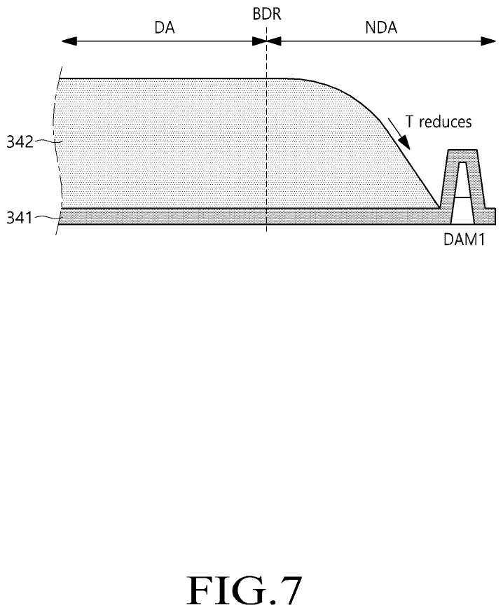

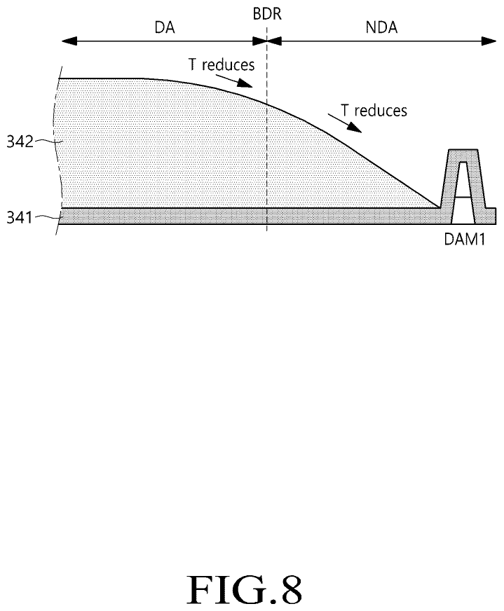

Next, FIG. 7 illustrates a second encapsulation layer 342 formed through a deposition process and FIG. 8 illustrates a second encapsulation layer 342 formed through an inkjet printing process in a display panel 110 of a touch display device 100 according to embodiments of the disclosure. Referring to FIGS. 7 and 8, the second encapsulation layer 342 which is an organic layer can be disposed on the first encapsulation layer 341 which is an inorganic layer, and can extend from the display area DA to the vicinity of the first dam DAM1.

Referring to FIG. 7, when the second encapsulation layer 342, which is an organic layer, is formed through a deposition process, the thickness T of the second encapsulation layer 342 can remain constant in the display area DA and can decrease in the non-display area NDA. When the second encapsulation layer 342, which is an organic layer, is formed through a deposition process, the thickness T of the second encapsulation layer 342 at a boundary point BDR between the display area DA and the non-display area NDA can be the same or substantially the same as the thickness T of the second encapsulation layer 342 in the display area DA.

Referring to FIG. 8, when the second encapsulation layer 342, which is an organic layer, is formed through an inkjet printing process, the thickness T of the second encapsulation layer 342 can decrease not only in the non-display area NDA, but also in the display area DA. In other words, when the second encapsulation layer 342, which is an organic layer, is formed through an inkjet printing process, the thickness T of the second encapsulation layer 342 can start to decrease from the display area DA.

Thus, when the second encapsulation layer 342, which is an organic layer, is formed through an inkjet printing process, the thickness T of the second encapsulation layer 342 at a boundary point BDR between the display area DA and the non-display area NDA can be smaller than the thickness T of the second encapsulation layer 342 in the display area DA.

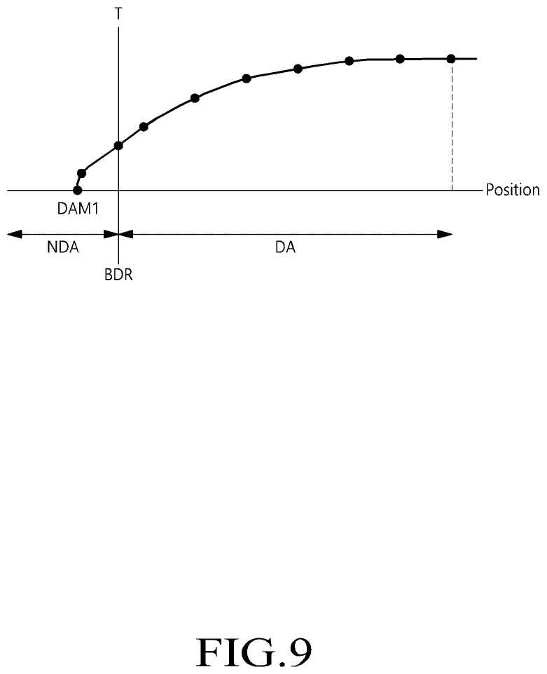

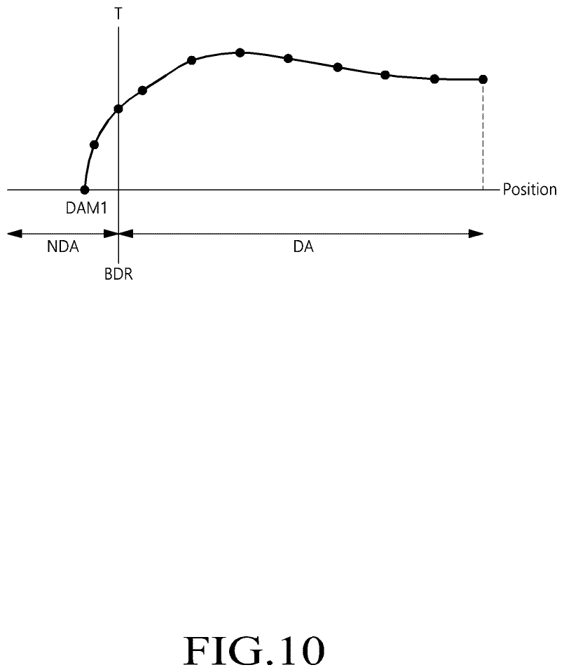

Hereinafter, when the second encapsulation layer 342, which is an organic layer, is formed through an inkjet printing process, the change in thickness according to the position of the second encapsulation layer 342 is described with reference to FIGS. 9 and 10. In particular, FIGS. 9 and 10 are graphs illustrating changes in the thickness T of a second encapsulation layer 342 formed through an inkjet printing process in a display panel 110 of a touch display device 100 according to embodiments of the disclosure.

Referring to FIG. 9, the thickness T of the second encapsulation layer 342 can decrease as the non-display area NDA approaches the boundary point BDR between the non-display area NDA and the display area DA from the center of the display area DA. As the first dam DAM1 in the non-display area NDA is approached from the boundary point BDR between the non-display area NDA and the display area DA, the thickness T of the second encapsulation layer 342 can further decrease. At the position of the first dam DAM1 disposed in the non-display area NDA, the thickness T of the second encapsulation layer 342 can be zero or substantially zero.

Referring to FIG. 10, as the boundary point BDR between the non-display area NDA and the display area DA is approached from the center of the display area DA, the thickness T of the second encapsulation layer 342 can increase slightly and then decrease. As the first dam DAM1 in the non-display area NDA is approached from the boundary point BDR between the non-display area NDA and the display area DA, the thickness T of the second encapsulation layer 342 can further decrease. At the position of the first dam DAM1 disposed in the non-display area NDA, the thickness T of the second encapsulation layer 342 can be zero or substantially zero. Thus, a change in thickness T according to a position with respect to the second encapsulation layer 342 can be as illustrated in FIG. 9 or 10.

Next, FIG. 11 illustrates parasitic capacitors C1, C2, and C3 formed on touch metals TM1, TM2, and TM3 disposed on a display panel 110 according to embodiments of the disclosure. Referring to FIG. 11, the encapsulation layer 200 can include a first encapsulation layer 341, a second encapsulation layer 342 on the first encapsulation layer 341, and a third encapsulation layer 343 on the second encapsulation layer 342. Each of the first encapsulation layer 341 and the third encapsulation layer 343 can be an inorganic layer, and the second encapsulation layer 342 can be an organic layer.

Referring to FIG. 11, according to the display panel 110 of the touch display device 100 according to embodiments of the disclosure, since the second encapsulation layer 342 is an organic layer, the thickness of the second encapsulation layer 342 can vary according to positions. In particular, the second encapsulation layer 342 can be formed by an inkjet printing process, so that the change in thickness of the second encapsulation layer 342 can occur not only in the non-display area NDA but also in the display area DA.

Referring to FIG. 11, in the display area DA, the thickness of the second encapsulation layer 342 can decrease as it approaches the boundary point BDR between the display area DA and the non-display area NDA. In the non-display area DA, the thickness of the second encapsulation layer 342 can further decrease as it approaches the first dam DAM1.

Referring to FIG. 11, a plurality of touch metals TM can be disposed on the encapsulation layer 200 and can include a first touch metal TM1 and a second touch metal TM2 disposed in the display area DA, and a third touch metal TM3 disposed in the non-display area NDA. That is, the first touch metal TM1 and the second touch metal TM2 can be disposed in the display area DA, and the third touch metal TM3 can be disposed in the non-display area NDA.

Also, each of the first touch metal TM1 and the second touch metal TM2 can constitute a touch electrode, and the third touch metal TM3 can constitute a touch routing line TL. For example, each of the first touch metal TM1 and the second touch metal TM2 can be one of the upper touch metal TMu and the lower touch metal TMd of FIG. 3. In addition, the third touch metal TM3 can be one of the upper touch metal TMu and the lower touch metal TMd of FIG. 3. Further, as described above, the second encapsulation layer 342, which is an organic layer, can be formed according to an inkjet printing process.

In addition, the upper surface of the second encapsulation layer 342 overlapping the first touch metal TM1 can be a flat surface or a first inclined surface, and the upper surface of the second encapsulation layer 342 overlapping the second touch metal TM2 can be a second inclined surface. Further, the upper surface of the second encapsulation layer 342 overlapping the third touch metal TM3 can be a third inclined surface. Also, the second inclined surface can be steeper than the first inclined surface, and the third inclined surface can be steeper than the second inclined surface.

In addition, the thickness of the second encapsulation layer 342 under the second touch metal TM2 in the display area DA can be smaller than the thickness of the second encapsulation layer 342 under the first touch metal TM1 in the display area DA. Also, the thickness of the second encapsulation layer 342 under the third touch metal TM3 in the non-display area NDA can be smaller than the thickness of the second encapsulation layer 342 under the second touch metal TM2 in the display area DA.

Further, as shown in FIG. 11, the display panel 110 of the touch display device 100 according to embodiments of the disclosure can further include a first display metal DM1 for display driving, overlapping the first touch metal TM1, a second display metal DM2 for display driving, overlapping the second touch metal TM2, and a third display metal DM3 for display driving, overlapping the third touch metal TM3.

In more detail, the first touch metal TM1 and the first display metal DM1 can overlap each other to form a first capacitor C1 having a first capacitance, and the second touch metal TM2 and the second display metal DM2 can overlap each other to form a second capacitor C2 having a second capacitance. Also, the third touch metal TM3 and the third display metal DM3 can overlap each other to form a third capacitor C3 having a third capacitance.

Due to the change in thickness according to the position of the second encapsulation layer 342, the separation distance between the second touch metal TM2 and the second display metal DM2 can be smaller than the separation distance between the first touch metal TM1 and the first display metal DM1, and the separation distance between the third touch metal TM3 and the third display metal DM3 can be smaller than the separation distance between the second touch metal TM2 and the second display metal DM2.

Assuming that the area where the first touch metal TM1 overlaps the first display metal DM1, the area where the second touch metal TM2 overlaps the second display metal DM2, and the area where the third touch metal TM3 overlaps the third display metal DM3 are the same, among the first capacitance of the first capacitor C1, the second capacitance of the second capacitor C2, and the third capacitance of the third capacitor C3, the third capacitance of the third capacitor C3 can be the largest, and the first capacitance of the first capacitor C1 can be the smallest.

In terms of touch sensing, the first capacitance of the first capacitor C1, the second capacitance of the second capacitor C2, and the third capacitance of the third capacitor C3 can be parasitic capacitances that do not need to be formed. Due to a change in thickness for each position (thickness deviation for each position) of the second encapsulation layer 342, the first capacitance of the first capacitor C1, the second capacitance of the second capacitor C2, and the third capacitance of the third capacitor C3 can be different from each other. Such a capacitance deviation (parasitic capacitance deviation) can deteriorate touch sensing performance. As described above, a phenomenon where the parasitic capacitance formed on the touch metal occurs differently according to the position and the touch sensing performance deteriorates can be referred to as a “touch non-uniformity phenomenon”.

In particular, as the second encapsulation layer 342 is formed by the inkjet printing process, a change in the thickness of the second encapsulation layer 342 can occur in the display area DA, and as a result, a capacitance deviation (parasitic capacitance deviation) between the first capacitor C1 and the second capacitor C2 formed in the display area DA can occur. Since the first capacitor C1 and the second capacitor C2 in the display area DA are formed in the first touch metal TM1 and the second touch metal TM2 constituting the touch electrode (touch sensor) in the display area DA, a capacitance deviation between the first capacitor C1 formed in the first touch metal TM1 and the second capacitor C2 formed in the second touch metal TM2 can significantly reduce touch sensing performance. In other words, if the second encapsulation layer 342 is formed by the inkjet printing process, the touch non-uniformity phenomenon can worsen.

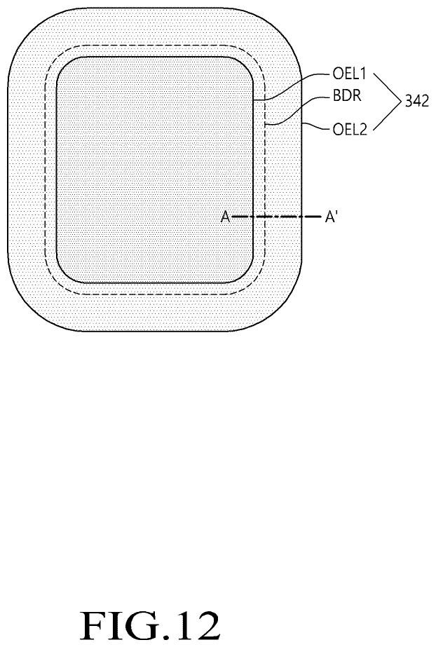

Accordingly, the touch display device 100 according to embodiments of the disclosure includes a structure for enhancing touch uniformity. Hereinafter, a structure for enhancing touch uniformity of the touch display device 100 according to embodiments of the disclosure is described in detail with reference to FIGS. 12 to 17.

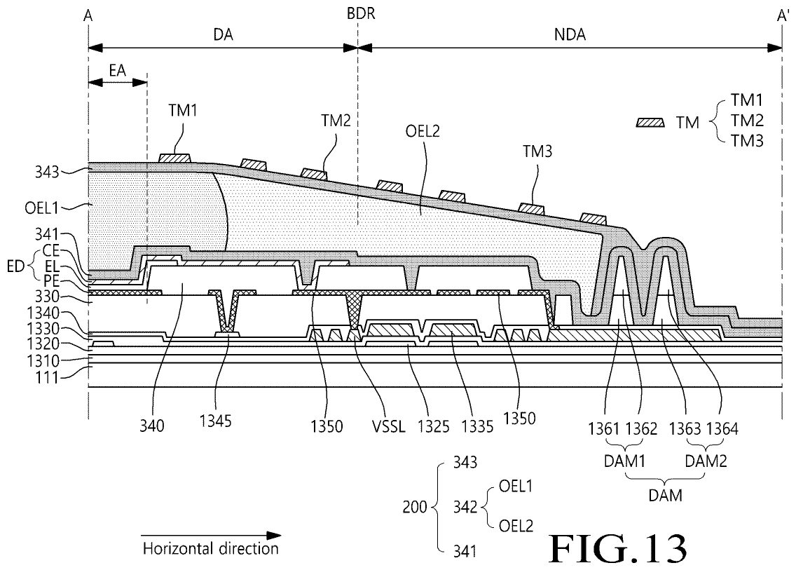

In particular, FIGS. 12 and 13 illustrate a second encapsulation layer 342 having a structure for enhancing touch uniformity and a display panel 110 including the same in a touch display device 100 according to an embodiment of the disclosure. FIG. 13 is a cross-sectional view taken along line A-A′ of FIG. 12.

Referring to FIG. 13, the display panel 110 includes a substrate 111 including a display area DA and a non-display area NDA outside the display area DA, a pixel electrode PE disposed on the substrate 111, a common electrode CE disposed on the pixel electrode PE, an encapsulation layer 200 disposed on the common electrode CE, and a plurality of touch metals TM disposed on the encapsulation layer 200.

The encapsulation layer 200 can include a first encapsulation layer 341 disposed on the common electrode CE, a second encapsulation layer 342 disposed on the first encapsulation layer 341, and a third encapsulation layer 343 disposed on the second encapsulation layer 342. The touch metals TM can be disposed on the third encapsulation layer 343.

Referring to FIG. 13, the display panel 110 can further include a buffer layer 1310 disposed on the substrate 111, a gate insulation layer 1320 disposed on the buffer layer 1310, an interlayer insulation layer 1330 disposed on the gate insulation layer 1320, and a passivation layer 1340 disposed on the interlayer insulation layer 1330.

The buffer layer 1310 of FIG. 13 can correspond to the first buffer layer 311 or the second buffer layer 321 of FIG. 3. Also, the gate insulation layer 1320 of FIG. 13 can correspond to the first gate insulation layer 312 or the second gate insulation layer 322 of FIG. 3. Further, the interlayer insulation layer 1330 of FIG. 13 can correspond to the first interlayer insulation layer 313 or the second interlayer insulation layer 323 of FIG. 3. Referring to FIG. 13, the display panel 110 can further include a planarization layer 330 disposed on the passivation layer 1340, and a bank 340 disposed on the planarization layer 330.

As shown in FIG. 13, the display panel can further include a first metal layer 1325 disposed between the gate insulation layer 1320 and the interlayer insulation layer 1330, a second metal layer 1335 disposed between the interlayer insulation layer 1330 and the passivation layer 1340, and a third metal layer 1345 disposed between the passivation layer 1340 and the planarization layer 330. Each of the first metal layer 1325, the second metal layer 1335, and the third metal layer 1345 can be utilized to form various electrodes or various signal lines. For example, the gate electrode of the transistor can be formed of a first metal layer 1325, and the source electrode or the drain electrode of the transistor can be formed of the second metal layer 1335. The connection electrode connecting the pixel electrode PE to the source electrode or the drain electrode of the transistor can also be formed of a third metal layer 1345.

For example, each of the two electrodes of the storage capacitor can be formed of one of the first metal layer 1325, the second metal layer 1335, and the third metal layer 1345. Also, the gate line can be formed of the first metal layer 1325. Signal lines such as data lines can be formed of the second metal layer 1335 or the third metal layer 1345. For example, the signal line extending in the horizontal direction (or the vertical direction) can be formed of the second metal layer 1335, and the signal line extending in the vertical direction (or the horizontal direction) can be formed of the third metal layer 1345.

Referring to FIG. 13, the display panel 110 can further include a first common voltage line VSSL to which a first common voltage VSS is applied and a common connection electrode 1350 electrically connecting the first common voltage line VSSL and the common electrode CE. Here, the first common voltage VSS can be referred to as a base voltage, a low-potential power voltage, or a low-potential voltage, and the first common voltage line VSSL can be referred to as a base voltage line, a low-potential power voltage line, or a low-potential voltage line.

The display panel 110 can also include a pixel electrode layer 1350 where the pixel electrode PE is disposed. As shown in FIG. 13, the common connection electrode 1350 can include the same material as the pixel electrode PE, and can be disposed in the pixel electrode layer 1350.

Referring to FIG. 13, the pixel electrode PE can be disposed on the planarization layer 330. Also, the bank 340 can be disposed on the pixel electrode PE and the planarization layer 330 and can have an opening overlapping a portion of the pixel electrode PE. The opening of the bank 340 can correspond to the emission area EA. In addition, the intermediate layer EL can be disposed on the pixel electrode PE, and the common electrode CE can be disposed on the intermediate layer EL. In the opening of the bank 340, the pixel electrode PE, the intermediate layer EL, and the common electrode CE can be stacked to form the light emitting element ED.

Further, the display panel 110 can include a dam structure DAM to prevent overflow of the second encapsulation layer 342, which is an organic layer. The dam structure DAM can be disposed further outside than the second encapsulation layer 342. For example, the dam structure DAM can be disposed on the side surfaces of the planarization layer 330 and the bank 340.

In addition, the dam structure DAM can include a first dam DAM1 including a first lower end portion 1361 and a first upper end portion 1362. Also, the first lower end portion 1361 can be formed of the same material as the bank 340, and the first upper end portion 1362 can be formed of the same material as the spacer that can be formed on the bank 340.

The dam structure DAM can further include a second dam DAM2 including a second lower end portion 1363 and a second upper end portion 1364. For example, the second lower end portion 1363 can be formed of the same material as the bank 340, and the second upper end portion 1364 can be formed of the same material as the spacer that can be formed on the bank 340.

Also, with reference to FIGS. 7, 8 and 13, the height of the DAM1 can be changed (increased or decrease). A higher height for the DAM1 can cause the second encapsulation layer 342 to have a flatter upper surface in the display area and non-display area. The location of the DAM1 can also be changed. For example, referring to FIG. 13, a higher DAM1 can cause the second encapsulation layer 342 to have a flatter upper surface in both the display area and non-display area.

Also, the second encapsulation layer 342 can be disposed to extend from the display area DA to a partial area of the non-display area NDA. The second encapsulation layer 342 can also be disposed inside the dam structure DAM. Further, the dam structure DAM can be disposed to surround the second encapsulation layer 342.

In addition, the first encapsulation layer 341 can be disposed to extend from the display area DA to a partial area of the non-display area NDA. As shown, the first encapsulation layer 341 can extend beyond the dam structure DAM and further outside than the dam structure DAM. Also, the third encapsulation layer 343 can be disposed to extend from the display area DA to a partial area of the non-display area NDA. The third encapsulation layer 343 can further extend beyond the dam structure DAM and further outside than the dam structure DAM.

In addition, the first encapsulation layer 341 and the third encapsulation layer 343 can include an inorganic material, and the second encapsulation layer 342 can include two or more different organic materials. According to the touch display device 100 according to embodiments of the disclosure, the thickness of the second encapsulation layer 342 can change in the display area DA and can decrease toward the outside of the display area DA.

Referring to FIGS. 12 and 13, according to the touch uniformity enhancing structure of the touch display device 100 according to embodiments of the disclosure, the second encapsulation layer 342 can include a first organic layer OEL1 having a first permittivity and a second organic layer OEL2 having a second permittivity different from the first permittivity. As shown, the second organic layer OEL2 can be disposed further outside than the first organic layer OEL1. In other words, the second organic layer OEL2 can be positioned on the side surface of the first organic layer OEL1 in the horizontal direction.

According to the touch display device 100 according to embodiments of the disclosure, the first organic material constituting the first organic layer OEL1 and the second organic material constituting the second organic layer OEL2 can be different from each other. For example, the first permittivity of the first organic material and the second permittivity of the second organic material can be different from each other.

Also, the second permittivity of the second organic layer OEL2 can be smaller than the first permittivity of the first organic layer OEL1 (first permittivity>second permittivity). For example, the first permittivity can be in the range of 2.7 to 3.3 [F/m], and the second permittivity can be in the range of 2.2 to 2.7 [F/m]. Referring to FIGS. 12 and 13, the first organic layer OEL1 can be formed through a first inkjet printing process and a first curing process, and the second organic layer OEL2 can be formed through a second inkjet printing process and a second curing process to form a touch uniformity enhancing structure according to embodiments of the disclosure.

During the first inkjet printing process and the first curing process, the first organic material in a liquid state can be finely sprayed into the formation area of the first organic layer OEL1 through a nozzle to form a film formed of the first organic material, and then the film formed of the first organic material can be cured to form the first organic layer OEL1. Thereafter, during the second inkjet printing process and the second curing process, the second organic material in a liquid state can be finely sprayed into the formation area of the second organic layer OEL2 through a nozzle to form a film formed of the second organic material, and then the film formed of the second organic material can be cured to form the second organic layer OEL2.

Referring to FIGS. 12 and 13, the minimum thickness of the second organic layer OEL2 can be smaller than the minimum thickness of the first organic layer OEL1. As shown in FIG. 13, a plurality of touch metals TM can include a first touch metal TM1 overlapping the first organic layer OEL1 and a second touch metal TM2 overlapping the second organic layer OEL2. Also, the second touch metal TM2 can be disposed further outside than the first touch metal TM1.

Referring to FIG. 13, the first touch metal TM1 and the second touch metal TM2 can be disposed in the display area DA. For example, each of the first touch metal TM1 and the second touch metal TM2 can constitute a touch electrode and can be one of the upper touch metal TMu and the lower touch metal TMd of FIG. 3.

In addition, the first touch metal TM1 can overlap the common electrode CE, and the second touch metal TM2 can overlap at least a portion of the common electrode CE. A separation distance between the second touch metal TM2 and the common electrode CE can also be smaller than a separation distance between the first touch metal TM1 and the common electrode CE.

Further, the first dam DAM1 can be positioned near the edge of the second encapsulation layer 342. Also, the first encapsulation layer 341 and the third encapsulation layer 343 can extend from the display area DA to the outside of the first dam DAM1 along the upper portion of the first dam DAM1. The first organic layer OEL1 and the second organic layer OEL2 included in the second encapsulation layer 342 can also be disposed inside the first dam DAM1. A separation distance between the first organic layer OEL1 and the first dam DAM1 can be larger than a separation distance between the second organic layer OEL2 and the first dam DAM1.

Referring to FIGS. 12 and 13, a boundary point BDR between the display area DA and the non-display area NDA can overlap the second organic layer OEL2 included in the second encapsulation layer 342. The touch metals TM can further include a third touch metal TM3 disposed further outside the second touch metal TM2. The third touch metal TM3 can be disposed in the non-display area NDA.

In addition, each of the first touch metal TM1 and the second touch metal TM2 can constitute a touch electrode. Also, the third touch metal TM3 can constitute a touch routing line TL. For example, each of the first touch metal TM1 and the second touch metal TM2 can be one of the upper touch metal TMu and the lower touch metal TMd of FIG. 3, and the third touch metal TM3 can be one of the upper touch metal TMu and the lower touch metal TMd of FIG. 3.

According to the display panel 110 of the touch display device 100 according to embodiments of the disclosure, the first organic layer OEL1 and the second organic layer OEL2 can be formed according to an inkjet printing process. Accordingly, the thickness of the second organic layer OEL2 under the second touch metal TM2 can be smaller than that of the first organic layer OEL1 under the first touch metal TM1.

Further, the thickness of the second organic layer OEL2 under the third touch metal TM3 can be smaller than that of the second organic layer OEL2 under the second touch metal TM2. The upper surface of the first organic layer OEL1 overlapping the first touch metal TM1 can be a flat surface or a first inclined surface. In addition, the upper surface of the second organic layer OEL2 overlapping the second touch metal TM2 can be a second inclined surface. The upper surface of the second organic layer OEL2 overlapping the third touch metal TM3 can be a third inclined surface. For example, the second inclined surface can be steeper than the first inclined surface, and the third inclined surface can be similar to the second inclined surface or steeper than the second inclined surface.

In addition, the display panel 110 can further include a first display metal for display driving, overlapping the first touch metal TM1, a second display metal for display driving, overlapping the second touch metal TM2, and a third display metal for display driving, overlapping the third touch metal TM3. For example, the first display metal can include the common electrode CE, the second display metal can include the common electrode CE, and the third display metal can include the common electrode CE or another metal layer. Here, the other metal layer can include at least one of the first metal layer 1325, the second metal layer 1335, the third metal layer 1345, and the pixel electrode layer 1350.

In addition, the first organic layer OEL1 and the second organic layer OEL2 can be formed by an inkjet printing process. Also, the second separation distance between the second touch metal TM2 and the second display metal DM2 can be smaller than the first separation distance between the first touch metal TM1 and the first display metal DM1. The third separation distance between the third touch metal TM3 and the third display metal DM3 can be smaller than or equal to the second separation distance between the second touch metal TM2 and the second display metal DM2.

Further, the first touch metal TM1 and the first display metal can overlap each other to form a first capacitor having a first capacitance. The second touch metal TM2 and the second display metal can overlap each other to form a second capacitor having a second capacitance. Also, the third touch metal TM3 and the third display metal can overlap each other to form a third capacitor having a third capacitance.

Referring to FIG. 13, even if the separation distance between the second touch metal TM2 and the second display metal DM2 is smaller than the separation distance between the first touch metal TM1 and the first display metal DM1, and the separation distance between the third touch metal TM3 and the third display metal DM3 is smaller than or equal to the separation distance between the second touch metal TM2 and the second display metal DM2, the second permittivity of the second organic layer OEL2 is smaller than the first permittivity of the first organic layer OEL1, so that the differences between the first capacitance, the second capacitance, and the third capacitance are within a predefined range. For this reason, the touch uniformity can be enhanced, and touch sensing performance can be increased.

In other words, according to the touch uniformity enhancing structure according to embodiments of the disclosure, the second encapsulation layer 342 can include a first organic layer OEL1 formed of a first organic material and a second organic layer OEL2 formed of a second organic material, and the second organic layer OEL2 can be positioned on the side surface (outer surface) of the first organic layer OEL1 in the horizontal direction. The second permittivity of the second organic layer OEL2 can be smaller than the first permittivity of the first organic layer OEL1.

According to the touch uniformity enhancing structure according to embodiments of the disclosure, even if the first to third touch metals TM1, TM2, and TM3 are at different positions, a difference in parasitic capacitance formed on each of the first to third touch metals TM1, TM2, and TM3 can be reduced. Therefore, the touch uniformity can be enhanced, and touch sensing performance can be increased.

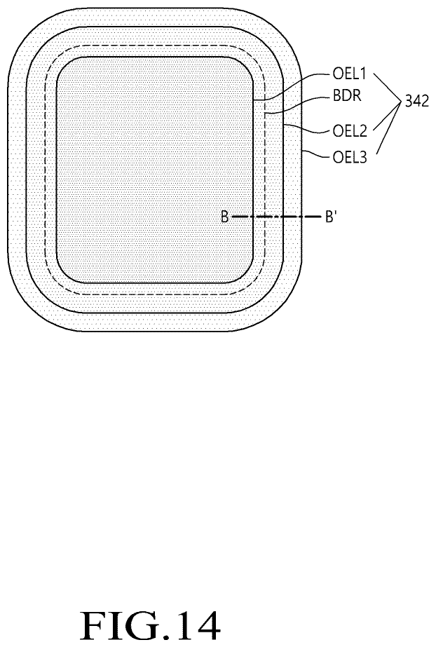

Hereinafter, a touch uniformity enhancing structure capable of further reducing a difference in parasitic capacitance formed on each of the first to third touch metals TM1, TM2, and TM3 at different positions is described with reference to FIGS. 14 to 17.

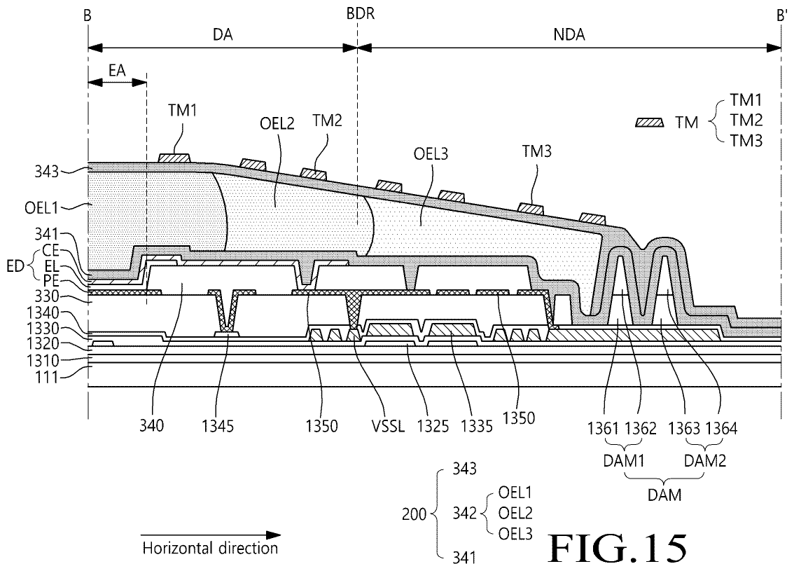

In particular, FIGS. 14 and 15 illustrate a second encapsulation layer 342 having a structure for enhancing touch uniformity and a display panel 110 including the same in a touch display device 100 according to an embodiment of the disclosure. FIG. 15 is a cross-sectional view taken along line B-B′ of FIG. 14. Descriptions of the same contents as those described with reference to FIGS. 12 and 13 may be omitted.

Referring to FIGS. 14 and 15, according to the touch uniformity enhancing structure according to embodiments of the disclosure, the second encapsulation layer 342 can further include a third organic layer OEL3 as well as the first organic layer OEL1 and the second organic layer OEL2. As shown, the third organic layer OEL3 can be disposed further outside than the second organic layer OEL2.

Referring to FIGS. 14 and 15, the third organic layer OEL3 can have a third permittivity different from the second permittivity of the second organic layer OEL2. For example, the third permittivity of the third organic layer OEL3 can be smaller than or equal to the second permittivity of the second organic layer OEL2.

Also, the first organic layer OEL1 can include a first organic material having a first permittivity, the second organic layer OEL2 can include a second organic material having a second permittivity, and the third organic layer OEL3 can include a third organic material having a third permittivity.

For example, the first organic material and the second organic material can be different from each other. Also, the second organic material and the third organic material can be the same as or different from each other, and the first organic material and the third organic material can be different from or the same as each other.

As another example, the first organic material, the second organic material, and the third organic material can all be different from each other. For example, the first permittivity of the first organic layer OEL1 and the second permittivity of the second organic layer OEL2 can be different from each other, and the second permittivity of the second organic layer OEL2 and the third permittivity of the third organic layer OEL3 can be the same as or different from each other. Also, the first permittivity of the first organic layer OEL1 and the third permittivity of the third organic layer OEL3 can be different from or the same as each other.

As another example, the first permittivity of the first organic layer OEL1, the second permittivity of the second organic layer OEL2, and the third permittivity of the third organic layer OEL3 can all be different from each other. For example, the second permittivity of the second organic layer OEL2 can be smaller than the first permittivity of the first organic layer OEL1, and the third permittivity of the third organic layer OEL3 can be smaller than or equal to the second permittivity of the second organic layer OEL2 (first permittivity>second permittivity≥third permittivity). Considering the size relationship, the first permittivity can be in the range of 2.7 to 3.3 [F/m], the second permittivity can be in the range of 2.5 to 3.0 [F/m], and the third permittivity can be in the range of 2.2 to 2.7 [F/m].

Referring to FIGS. 14 and 15, the first organic layer OEL1 can be formed through a first inkjet printing process and a first curing process, the second organic layer OEL2 can be formed through a second inkjet printing process and a second curing process, and the third organic layer OEL3 can be formed through a third inkjet printing process and a third curing process. During the first inkjet printing process and the first curing process, the first organic material in a liquid state can be finely sprayed into the formation area of the first organic layer OEL1 through a nozzle to form a film formed of the first organic material, and then the film formed of the first organic material can be cured to form the first organic layer OEL1.

Thereafter, during the second inkjet printing process and the second curing process, the second organic material in a liquid state can be finely sprayed into the formation area of the second organic layer OEL2 through a nozzle to form a film formed of the second organic material, and then the film formed of the second organic material can be cured to form the second organic layer OEL2. During the third inkjet printing process and the third curing process, the third organic material in a liquid state can be finely sprayed into the formation area of the third organic layer OEL3 through a nozzle to form a film formed of the third organic material, and then the film formed of the third organic material can be cured to form the third organic layer OEL3.

Referring to FIGS. 14 and 15, the minimum thickness of the second organic layer OEL2 can be smaller than the minimum thickness of the first organic layer OEL1. Also, the minimum thickness of the third organic layer OEL3 can be smaller than the minimum thickness of the second organic layer OEL2.

Referring to FIG. 15, the touch metals TM can include a first touch metal TM1 overlapping the first organic layer OEL1, a second touch metal TM2 overlapping the second organic layer OEL2, and a third touch metal TM3 overlapping the third organic layer OEL3. As shown, the second touch metal TM2 can be disposed further outside than the first touch metal TM1, and the third touch metal TM3 can be disposed further outside than the second touch metal TM2.

In addition, the first touch metal TM1 and the second touch metal TM2 can be disposed in the display area DA, and the third touch metal TM3 can be disposed in the non-display area NDA. Also, each of the first touch metal TM1 and the second touch metal TM2 can constitute a touch electrode, and the third touch metal TM3 can constitute a touch routing line TL. Each of the first touch metal TM1 and the second touch metal TM2 can be one of the upper touch metal TMu and the lower touch metal TMd of FIG. 3, and the third touch metal TM3 can be one of the upper touch metal TMu and the lower touch metal TMd of FIG. 3.

According to the display panel 110 of the touch display device 100 according to embodiments of the disclosure, the first organic layer OEL1, the second organic layer OEL2, and the third organic layer OEL3 can be formed according to the inkjet printing process. Accordingly, the thickness of the second organic layer OEL2 under the second touch metal TM2 can be smaller than that of the first organic layer OEL1 under the first touch metal TM1. Also, the thickness of the second organic layer OEL2 under the second touch metal TM2 can be smaller than that of the first organic layer OEL1 under the first touch metal TM1.

In addition, the upper surface of the first organic layer OEL1 overlapping the first touch metal TM1 can be a flat surface or a first inclined surface. The upper surface of the second organic layer OEL2 overlapping the second touch metal TM2 can be a second inclined surface, and the upper surface of the third organic layer OEL3 overlapping the third touch metal TM3 can be a third inclined surface. Further, the second inclined surface can be steeper than the first inclined surface, and the third inclined surface can be steeper than the second inclined surface.

The display panel 110 can further include a first display metal DM1 for display driving, overlapping the first touch metal TM1, a second display metal DM2 for display driving, overlapping the second touch metal TM2, and a third display metal DM3 for display driving, overlapping the third touch metal TM3.

The first touch metal TM1 and the first display metal DM1 can overlap each other to form a first capacitor C1 having a first capacitance, and the second touch metal TM2 and the second display metal DM2 can overlap each other to form a second capacitor C2 having a second capacitance. The third touch metal TM3 and the third display metal DM3 can also overlap each other to form a third capacitor C3 having a third capacitance.

Referring to FIG. 15, according to the structure of the second encapsulation layer 342, a separation distance between the third touch metal TM3 and the third display metal DM3 can be smaller than a separation distance between the second touch metal TM2 and the second display metal DM2. Further, the separation distance between the second touch metal TM2 and the second display metal DM2 can be smaller than the separation distance between the first touch metal TM1 and the first display metal DM1.

Referring to FIG. 15, even if the separation distance between the second touch metal TM2 and the second display metal DM2 is smaller than the separation distance between the first touch metal TM1 and the first display metal DM1, and the separation distance between the third touch metal TM3 and the third display metal DM3 is smaller than or equal to the separation distance between the second touch metal TM2 and the second display metal DM2, the second permittivity of the second organic layer OEL2 is smaller than the first permittivity of the first organic layer OEL1, and the third permittivity of the third organic layer OEL3 is equal to or smaller than the second permittivity of the second organic layer OEL2 (first permittivity>second permittivity≥third permittivity), so that the differences between the first capacitance, the second capacitance, and the third capacitance within a predefined range.

In other words, the second encapsulation layer 342 can include a first organic layer OEL1 formed of a first organic material, a second organic layer OEL2 formed of a second organic material, and a third organic layer OEL3 formed of a third organic material, and the first organic layer OEL1, the second organic layer OEL2, and the third organic layer OEL3 can be positioned next to each other in the horizontal direction. The second permittivity of the second organic layer OEL2 can be smaller than the first permittivity of the first organic layer OEL1, and the third permittivity of the third organic layer OEL3 can be smaller than or equal to the second permittivity of the second organic layer OEL2.

In addition, even if the first to third touch metals TM1, TM2, and TM3 are at different positions, a difference in parasitic capacitance formed on each of the first to third touch metals TM1, TM2, and TM3 can be reduced. Therefore, touch uniformity can be further enhanced, and touch sensing performance can be further increased.

Referring to FIG. 15, the first dam DAM1 can be positioned near the edge of the second encapsulation layer 342. Also, the first encapsulation layer 341 and the third encapsulation layer 343 can extend from the display area DA to the outside of the first dam DAM1 along the upper portion of the first dam DAM1.

As shown in FIG. 15, the first organic layer OEL1, the second organic layer OEL2, and the third organic layer OEL3 can be disposed inside the first dam DAM1. A separation distance between the first organic layer OEL1 and the first dam DAM1 can be larger than a separation distance between the second organic layer OEL2 and the first dam DAM1. A separation distance between the second organic layer OEL2 and the first dam DAM1 can be larger than a separation distance between the third organic layer OEL3 and the first dam DAM1.

A boundary point BDR between the display area DA and the non-display area NDA can overlap the second organic layer OEL2 or the third organic layer OEL3. For example, as illustrated in FIGS. 14 and 15, the boundary point BDR between the display area DA and the non-display area NDA can overlap the second organic layer OEL2.

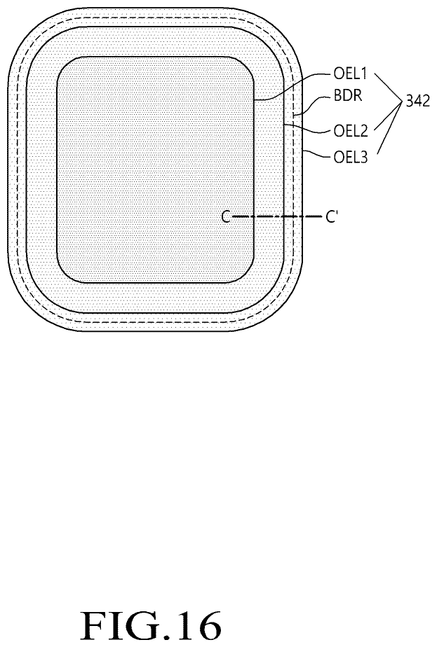

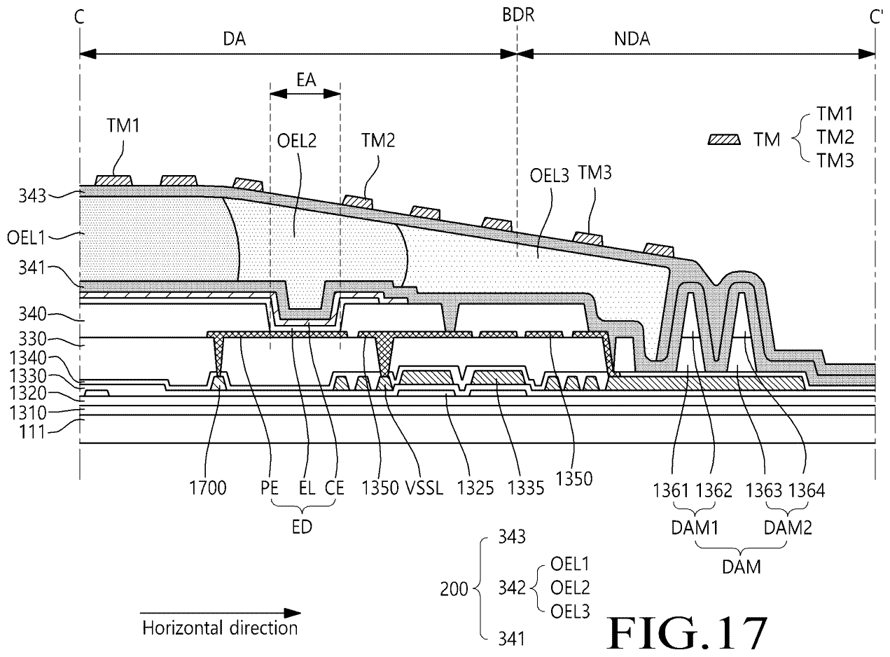

Next, FIGS. 16 and 17 illustrate a second encapsulation layer 342 having a structure for enhancing touch uniformity and a display panel 110 including the same in a touch display device 100 according to an embodiment of the disclosure. In particular, FIG. 17 is a cross-sectional view taken along line C-C′ of FIG. 16. Descriptions of the same contents as those described with reference to FIGS. 12 to 15 can be omitted.

The structure of the second encapsulation layer 342 of FIGS. 16 and 17 is the same as the structure of the second encapsulation layer 342 of FIGS. 14 and 15. However, there is a difference in the boundary point BDR between the display area DA and the non-display area NDA.

Referring to FIGS. 16 and 17, a boundary point BDR between the display area DA and the non-display area NDA can overlap the third organic layer OEL3. A touch display device 100 having a touch uniformity enhancing structure according to embodiments of the disclosure described above can include a substrate 111 including a display area DA where an image is displayed and a non-display area NDA outside the display area DA, a pixel electrode PE disposed on the substrate 111, a common electrode CE disposed on the pixel electrode PE, an organic layer 342 disposed on the common electrode CE, and a plurality of touch metals TM disposed on the organic layer 342.

In addition, the organic layer 342 can include two or more different organic materials in a horizontal direction from the display area DA to the non-display area NDA. Also, the organic layer 342 can include a first organic layer OEL1 including a first organic material, and a second organic layer OEL2 including a second organic material different from the first organic material. As shown in FIG. 15, the second organic layer OEL2 can be disposed further outside than the first organic layer OEL1 in the horizontal direction.

Also, the organic layer 342 can include a third organic layer OEL3 including a third organic material different from the second organic material. The third organic layer OEL3 can be disposed further outside than the second organic layer OEL2 in the horizontal direction.

In addition, the pixel electrode PE can be electrically connected to the metal pattern 1700 through holes of the planarization layer 330 and the passivation layer 1340. Further, the metal pattern 1700 can be disposed in the third metal layer 1345, and the metal pattern 1700 can be the source electrode or the drain electrode of the transistor in the subpixel circuit.

Embodiments of the disclosure described above are briefly described below.

A touch display device according to embodiments of the disclosure includes a substrate having a display area displaying an image and a non-display area outside the display area, a pixel electrode disposed on the substrate, a common electrode disposed on the pixel electrode, a first encapsulation layer disposed on the common electrode, a second encapsulation layer disposed on the first encapsulation layer, a third encapsulation layer disposed on the second encapsulation layer, and a plurality of touch metals disposed on the third encapsulation layer.

The second encapsulation layer can include two or more organic layers in a horizontal direction. For example, the second encapsulation layer can include a first organic layer having a first permittivity, and a second organic layer having a second permittivity different from the first permittivity and disposed further outside than the first organic layer.

In addition, the first encapsulation layer and the third encapsulation layer can include an inorganic material. The second encapsulation layer can also include two or more different organic materials. A thickness of the second encapsulation layer can be changed in the display area and decrease outward of the display area.

In addition, a minimum thickness of the second organic layer can be smaller than a minimum thickness of the first organic layer. Further, the second permittivity can be smaller than the first permittivity, and the touch metals can include a first touch metal overlapping the first organic layer, and a second touch metal disposed further outside than the first touch metal and overlapping the second organic layer.

Further, the first touch metal and the second touch metal can be disposed in the display area, and the first touch metal can overlap the common electrode. The second touch metal can also overlap at least a portion of the common electrode, and a separation distance between the second touch metal and the common electrode can be smaller than a separation distance between the first touch metal and the common electrode.

The touch display device can also include a first dam positioned adjacent to an edge of the second encapsulation layer with the first encapsulation layer and the third encapsulation layer extending from the display area to an outer perimeter of the first dam along an upper portion of the first dam.

Also, the first organic layer and the second organic layer can be disposed inside the first dam, and a separation distance between the first organic layer and the first dam can be larger than a separation distance between the second organic layer and the first dam. Further, a boundary point between the display area and the non-display area can overlap the second organic layer.

As another example, the second encapsulation layer can further include a third organic layer in addition to the first organic layer and the second organic layer. Also, the third organic layer has a third permittivity different from the second permittivity and can be positioned further outside than the second organic layer.

As described above, a minimum thickness of the third organic layer can be smaller than a minimum thickness of the second organic layer. Further, the third permittivity can be the second permittivity or less.

In addition, the touch metals can include a first touch metal overlapping the first organic layer, a second touch metal disposed further outside than the first touch metal and overlapping the second organic layer, and a third touch metal disposed further outside than the second touch metal and overlapping the third organic layer. The first touch metal and the second touch metal can also be disposed in the display area, and the third touch metal can be disposed in the non-display area.

In addition, an upper surface of the first organic layer overlapping the first touch metal can be a flat surface or a first inclined surface, an upper surface of the second organic layer overlapping the second touch metal can be a second inclined surface, and an upper surface of the third organic layer overlapping the third touch metal can be a third inclined surface. The second inclined surface can be steeper than the first inclined surface, and the third inclined surface can be steeper than the second inclined surface.

Further, the touch display device can further include a first display metal for display driving, overlapping the first touch metal, a second display metal for display driving, overlapping the second touch metal, and a third display metal for display driving, overlapping the third touch metal.

As described above, a separation distance between the second touch metal and the second display metal can be smaller than a separation distance between the first touch metal and the first display metal. Also, a separation distance between the third touch metal and the third display metal can be equal to or smaller than a separation distance between the second touch metal and the second display metal.

Further, the display area can include a plurality of touch electrodes for touch sensing. In particular, the non-display area can include a plurality of touch pads and a plurality of touch routing lines electrically connecting the touch electrodes and the touch pads. Each of the first touch metal and the second touch metal can constitute one of the touch electrodes, and the third touch metal can constitute one of the touch routing lines.

The touch display device can also include a metal layer positioned closer to the substrate than the common electrode. For example, the first display metal can be a common electrode, the second display metal can be a common electrode, and the third display metal can be a common electrode or a metal layer.

Also, the first touch metal and the first display metal can overlap each other to form a first capacitor having a first capacitance, the second touch metal and the second display metal can overlap each other to form a second capacitor having a second capacitance, and the third touch metal and the third display metal can overlap each other to form a third capacitor having a third capacitance. A difference between the first capacitance, the second capacitance, and the third capacitance can also be within a predefined range.

The touch display device can also include a first dam positioned adjacent to an edge of the second encapsulation layer. Also, the first encapsulation layer and the third encapsulation layer can extend from the display area to an outer perimeter of the first dam along an upper portion of the first dam. The first organic layer, the second organic layer, and the third organic layer can also be disposed inside the first dam.

Further, a separation distance between the first organic layer and the first dam can be larger than a separation distance between the second organic layer and the first dam, and a separation distance between the second organic layer and the first dam can be larger than a separation distance between the third organic layer and the first dam. A boundary point between the display area and the non-display area can overlap the second organic layer or the third organic layer.

A touch display device according to embodiments of the disclosure can also include a substrate including a display area displaying an image and a non-display area outside the display area, a pixel electrode disposed on the substrate, a common electrode disposed on the pixel electrode, an organic layer (which can be the above-mentioned second encapsulation layer) disposed on the common electrode, and a plurality of touch metals disposed on the organic layer. The organic layer can include two or more different organic materials in a horizontal direction from the display area to the non-display area.

In more detail, the organic layer can include a first organic layer including a first organic material, and a second organic layer including a second organic material different from the first organic material. The second organic layer can be disposed further outside than the first organic layer in the horizontal direction. Further, the organic layer can further include a third organic layer including a third organic material different from the second organic material. The third organic layer can be disposed further outside than the second organic layer in the horizontal direction.

According to embodiments of the disclosure described above, it is possible to shorten the panel manufacturing time and enable eco-friendly panel manufacturing, mass production, or large-scale panel manufacturing by forming an encapsulation structure through an inkjet printing process. Further, it is possible to shorten the panel manufacturing time and enable eco-friendly panel manufacturing, mass production, or large-scale panel manufacturing by forming a touch sensor structure on an encapsulation structure formed through an inkjet printing process. It is also possible to enhance touch sensitivity by increasing the uniformity of touch sensitivity by forming an encapsulation layer with two or more different organic materials in a horizontal direction.

The above-described embodiments are merely examples, and it will be appreciated by one of ordinary skill in the art various changes can be made thereto without departing from the scope of the disclosure. Accordingly, the embodiments set forth herein are provided for illustrative purposes, but not to limit the scope of the disclosure, and should be appreciated that the scope of the disclosure is not limited by the embodiments.

What is claimed is:

1. A touch display device, comprising:
a substrate including a display area and a non-display area;
a pixel electrode disposed on the substrate;
a common electrode disposed on the pixel electrode;
a first encapsulation layer disposed on the common electrode;
a second encapsulation layer disposed on the first encapsulation layer;
a third encapsulation layer disposed on the second encapsulation layer; and
a plurality of touch metals disposed on the third encapsulation layer,
wherein the second encapsulation layer includes:
a first organic layer having a first permittivity; and
a second organic layer having a second permittivity different from the first permittivity and disposed outside the first organic layer.

2. The touch display device of claim 1, wherein the first encapsulation layer and the third encapsulation layer include an inorganic material,
wherein the second encapsulation layer includes two or more different organic materials, and
wherein a thickness of the second encapsulation layer changes in the display area and decreases in the non-display area.

3. The touch display device of claim 1, wherein a minimum thickness of the second organic layer is smaller than a minimum thickness of the first organic layer.

4. The touch display device of claim 1, wherein the second permittivity is smaller than the first permittivity.

5. The touch display device of claim 1, wherein the plurality of touch metals include:
a first touch metal overlapping the first organic layer; and
a second touch metal disposed outside the first touch metal and overlapping the second organic layer.

6. The touch display device of claim 5, wherein the first touch metal and the second touch metal are disposed in the display area,
wherein the first touch metal overlaps the common electrode,
wherein the second touch metal overlaps at least a portion of the common electrode, and
wherein a separation distance between the second touch metal and the common electrode is smaller than a separation distance between the first touch metal and the common electrode.

7. The touch display device of claim 1, further comprising:
a first dam positioned adjacent to an edge of the second encapsulation layer,
wherein the first encapsulation layer and the third encapsulation layer extend from the display area to an outer perimeter of the first dam along an upper portion of the first dam,
wherein the first organic layer and the second organic layer are disposed inside the first dam, and
wherein a separation distance between the first organic layer and the first dam is larger than a separation distance between the second organic layer and the first dam.

8. The touch display device of claim 1, wherein a boundary point between the display area and the non-display area overlaps the second organic layer.

9. The touch display device of claim 1, wherein the second encapsulation layer further includes a third organic layer having a third permittivity different from the second permittivity and disposed outside the second organic layer.

10. The touch display device of claim 9, wherein a minimum thickness of the third organic layer is smaller than a minimum thickness of the second organic layer.

11. The touch display device of claim 9, wherein the third permittivity is a value equal to the second permittivity or less.

12. The touch display device of claim 9, wherein the plurality of touch metals include:
a first touch metal overlapping the first organic layer;
a second touch metal disposed outside the first touch metal and overlapping the second organic layer; and
a third touch metal disposed outside the second touch metal and overlapping the third organic layer.

13. The touch display device of claim 12, wherein the first touch metal and the second touch metal are disposed in the display area,
wherein the third touch metal is disposed in the non-display area,
wherein an upper surface of the first organic layer overlapping the first touch metal is a flat surface or a first inclined surface,
wherein an upper surface of the second organic layer overlapping the second touch metal is a second inclined surface,
wherein an upper surface of the third organic layer overlapping the third touch metal is a third inclined surface, and
wherein the second inclined surface is steeper than the first inclined surface, and the third inclined surface is steeper than the second inclined surface.

14. The touch display device of claim 12, further comprising:
a first display metal for display driving, overlapping the first touch metal;
a second display metal for display driving, overlapping the second touch metal; and
a third display metal for display driving, overlapping the third touch metal,
wherein a separation distance between the second touch metal and the second display metal is smaller than a separation distance between the first touch metal and the first display metal, and
wherein a separation distance between the third touch metal and the third display metal is equal to or smaller than a separation distance between the second touch metal and the second display metal.

15. The touch display device of claim 12, wherein the display area includes a plurality of touch electrodes for touch sensing,
wherein the non-display area includes a plurality of touch pads and a plurality of touch routing lines electrically connecting the plurality of touch electrodes and the plurality of touch pads, and
wherein each of the first touch metal and the second touch metal constitutes one of the plurality of touch electrodes, and the third touch metal constitutes one of the plurality of touch routing lines.

16. The touch display device of claim 9, further comprising:
a first dam positioned adjacent to an edge of the second encapsulation layer,
wherein the first encapsulation layer and the third encapsulation layer extend from the display area to an outer perimeter of the first dam along an upper portion of the first dam,
wherein the first organic layer, the second organic layer, and the third organic layer are disposed inside the first dam,
wherein a separation distance between the first organic layer and the first dam is larger than a separation distance between the second organic layer and the first dam, and
wherein a separation distance between the second organic layer and the first dam is larger than a separation distance between the third organic layer and the first dam.

17. The touch display device of claim 9, wherein a boundary point between the display area and the non-display area overlaps the second organic layer or the third organic layer.

18. A touch display device, comprising:
a substrate including a display area and a non-display area;
a pixel electrode disposed on the substrate;
a common electrode disposed on the pixel electrode;
a first inorganic encapsulation layer disposed on the common electrode;
an ink-injected organic second encapsulation layer disposed on the first inorganic encapsulation layer;
a third inorganic encapsulation layer disposed on the second ink-injected organic second encapsulation layer; and
a first touch metal disposed on the third inorganic encapsulation layer and overlapping a first display metal in the display area and forming a first capacitance;
a second touch metal disposed on the third inorganic encapsulation layer and overlapping a second display metal in the display area and forming a second capacitance; and
a third touch metal disposed on the third inorganic encapsulation layer and overlapping a third display metal in the non-display area and forming a third capacitance,
wherein a first separation distance between the first touch metal and the first display metal is greater than a second separation distance between the second touch metal and the second display metal,
wherein a first permittivity of the ink-injected organic second encapsulation layer between the first touch metal and the first display metal is greater than a second permittivity of the ink-injected organic second encapsulation layer between the second touch metal and the second display metal such that a parasitic capacitance between the first capacitance and the second capacitance is within a predefined range.

19. The touch display device of claim 18, wherein a third separation distance between the third touch metal and the third display metal is less than the second separation distance between the second touch metal and the second display metal, and
wherein a third permittivity of the ink-injected organic second encapsulation layer between the third touch metal and the third display metal is less than the second permittivity of the ink-injected organic second encapsulation layer between the second touch metal and the second display metal such that a parasitic capacitance between the first capacitance, the second capacitance and the third capacitance is within a predefined range.

20. The touch display device of claim 19, wherein the ink-injected organic second encapsulation layer includes a first organic material having the first permittivity, a second organic material having the second permittivity and third organic material having the first permittivity.

21. The touch display device of claim 18, wherein the ink-injected organic second encapsulation layer includes at least first and second different organic materials in a horizontal direction from the display area to the non-display area.

22. The touch display device of claim 21, wherein the first organic material is disposed between the first touch metal and the first display metal, and the second organic material is disposed between the second touch metal and the second display metal.

23. The touch display device of claim 21, wherein the ink-injected organic second encapsulation layer includes at least a third different organic material in the horizontal direction from the display area to the non-display area, and
wherein the third organic material is disposed between the third touch metal and the third display metal.
